(19) United States
(12) Patent Application Publication
(10) Pub. No.: US 2025/0194212 A1
(43) Pub. Date: Jun. 12, 2025

(54) SEMICONDUCTOR DEVICE WITH WRAP-AROUND CONTACT HAVING NON-UNIFORM THICKNESS

(71) Applicant: INTERNATIONAL BUSINESS MACHINES CORPORATION, ARMONK, NY (US)

(72) Inventors: Minhaz Abedin, Albany, NY (US); Tao Li, Slingerlands, NY (US); Ruilong Xie, Niskayuna, NY (US); Oleg Gluschenkov, Tannersville, NY (US)

(21) Appl. No.: 18/530,999

(22) Filed: Dec. 6, 2023

(51) Int. Cl. H01L 29/417; H01L 23/528; H01L 29/06; H01L 29/423; H01L 29/775; H01L 29/786

(52) U.S. Cl. CPC H10D 64/254; H01L 23/5286; H10D 30/43; H10D 30/6735; H10D 30/6757; H10D 62/121

(57) ABSTRACT

A semiconductor device is provided. The semiconductor device includes a nanosheet stack disposed on a substrate. The semiconductor device also includes a source/drain epitaxial layer disposed on the substrate adjacent to the nanosheet stack. The semiconductor device also includes a source/drain contact formed in contact with the source/drain epitaxial layer. The source/drain contact includes a wrap-around portion that wraps around sidewall surfaces of the source/drain epitaxial layer, and an extending portion that extends from the wrap-around portion, where the wrap-around portion has a non-uniform thickness.

### BACKGROUND

The present disclosure relates to fabrication methods and resulting structures for semiconductor devices. More specifically, the present disclosure relates to fabrication methods and resulting structures for semiconductors including a wrap-around contact.

In certain semiconductor device fabrication processes, a large number of semiconductor devices, such as n-type field effect transistors (nFETs) and p-type field effect transistors (pFETs), may be fabricated on a single wafer. Non-planar transistor device architectures (e.g., fin-type FETs (FinFETs) and nanosheet FETs) can provide increased device density and increased performance over planar transistors. Epitaxial layers of certain semiconductor devices are connected to metal contacts. The thicknesses of certain portions of these metal contacts may affect the resistance and/or capacitance between the gate contacts and the gate electrodes for the semiconductor devices.

### SUMMARY

Embodiments of the present disclosure relate to a semiconductor device. The semiconductor device includes a nanosheet stack disposed on a substrate. The semiconductor device also includes a source/drain epitaxial layer disposed on the substrate adjacent to the nanosheet stack. The semiconductor device also includes a source/drain contact formed in contact with the source/drain epitaxial layer. The source/drain contact includes a wrap-around portion that wraps around sidewall surfaces of the source/drain epitaxial layer, and an extending portion that extends from the wrap-around portion, where the wrap-around portion has a non-uniform thickness.

Embodiments of the present disclosure relate to an electronic device that includes a semiconductor device. The semiconductor device includes a nanosheet stack disposed on a substrate. The semiconductor device also includes a source/drain epitaxial layer disposed on the substrate adjacent to the nanosheet stack. The semiconductor device also includes a source/drain contact formed in contact with the source/drain epitaxial layer. The source/drain contact includes a wrap-around portion that wraps around sidewall surfaces of the source/drain epitaxial layer, and an extending portion that extends from the wrap-around portion, where the wrap-around portion has a non-uniform thickness.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A is a cross-sectional view of a semiconductor device at an intermediate stage of the fabrication process and taken along the X1-X2 line shown in FIG. 1C, according to embodiments.

FIG. 1B is a cross-sectional view of the semiconductor device of FIG. 1B taken along the Y line shown in FIG. 1C, according to embodiments.

FIG. 1C is a top-down view of the semiconductor device of FIG. 1A, according to embodiments.

FIG. 2A is a cross-sectional view of a semiconductor device of FIG. 1A at a subsequent stage of the fabrication process and taken along the X1-X2 line shown in FIG. 1C, according to embodiments.

FIG. 2B is a cross-sectional view of a semiconductor device of FIG. 1B at a subsequent stage of the fabrication process and taken along the Y1-Y2 line shown in FIG. 1C, according to embodiments.

FIG. 3A is a cross-sectional view of a semiconductor device of FIG. 2A at a subsequent stage of the fabrication process and taken along the X1-X2 line shown in FIG. 1C, according to embodiments.

FIG. 3B is a cross-sectional view of a semiconductor device of FIG. 2B at a subsequent stage of the fabrication process and taken along the Y1-Y2 line shown in FIG. 1C, according to embodiments.

FIG. 4A is a cross-sectional view of a semiconductor device of FIG. 3A at a subsequent stage of the fabrication process and taken along the X1-X2 line shown in FIG. 1C, according to embodiments.

FIG. 4B is a cross-sectional view of a semiconductor device of FIG. 3B at a subsequent stage of the fabrication process and taken along the Y1-Y2 line shown in FIG. 1C, according to embodiments.

FIG. 5A is a cross-sectional view of a semiconductor device of FIG. 4A at a subsequent stage of the fabrication process and taken along the X1-X2 line shown in FIG. 1C, according to embodiments.

FIG. 5B is a cross-sectional view of a semiconductor device of FIG. 4B at a subsequent stage of the fabrication process and taken along the Y1-Y2 line shown in FIG. 1C, according to embodiments.

FIG. 6A is a cross-sectional view of a semiconductor device of FIG. 5A at a subsequent stage of the fabrication process and taken along the X1-X2 line shown in FIG. 1C, according to embodiments.

FIG. 6B is a cross-sectional view of a semiconductor device of FIG. 5B at a subsequent stage of the fabrication process and taken along the Y1-Y2 line shown in FIG. 1C, according to embodiments.

FIG. 7A is a cross-sectional view of a semiconductor device of FIG. 6A at a subsequent stage of the fabrication process and taken along the X1-X2 line shown in FIG. 1C, according to embodiments.

FIG. 7B is a cross-sectional view of a semiconductor device of FIG. 6B at a subsequent stage of the fabrication process and taken along the Y1-Y2 line shown in FIG. 1C, according to embodiments.

FIG. 8A is a cross-sectional view of a semiconductor device of FIG. 7A at a subsequent stage of the fabrication process and taken along the X1-X2 line shown in FIG. 1C, according to embodiments.

FIG. 8B is a cross-sectional view of a semiconductor device of FIG. 7B at a subsequent stage of the fabrication process and taken along the Y1-Y2 line shown in FIG. 1C, according to embodiments.

FIG. 9A is a cross-sectional view of a semiconductor device of FIG. 8A at a subsequent stage of the fabrication process and taken along the X1-X2 line shown in FIG. 1C, according to embodiments.

FIG. 9B is a cross-sectional view of a semiconductor device of FIG. 8B at a subsequent stage of the fabrication process and taken along the Y1-Y2 line shown in FIG. 1C, according to embodiments.

FIG. 10A is a cross-sectional view of a semiconductor device of FIG. 9A at a subsequent stage of the fabrication process and taken along the X1-X2 line shown in FIG. 1C, according to embodiments.

FIG. 10B is a cross-sectional view of a semiconductor device of FIG. 9B at a subsequent stage of the fabrication process and taken along the Y1-Y2 line shown in FIG. 1C, according to embodiments.

FIG. 11A is a cross-sectional view of a semiconductor device of FIG. 10A at a subsequent stage of the fabrication process and taken along the X1-X2 line shown in FIG. 1C, according to embodiments.

FIG. 11B is a cross-sectional view of a semiconductor device of FIG. 10B at a subsequent stage of the fabrication process and taken along the Y1-Y2 line shown in FIG. 1C, according to embodiments.

FIG. 12A is a cross-sectional view of a semiconductor device of FIG. 11A at a according to embodiments.

FIG. 12B is a cross-sectional view of a semiconductor device of FIG. 11B at a according to embodiments.

FIG. 13A is a cross-sectional view of a semiconductor device of FIG. 12A at a subsequent stage of the fabrication process and taken along the X1-X2 line shown in FIG. 1C, according to embodiments.

FIG. 13B is a cross-sectional view of a semiconductor device of FIG. 12B at a subsequent stage of the fabrication process and taken along the Y1-Y2 line shown in FIG. 1C, according to embodiments.

FIG. 14A is a cross-sectional view of a semiconductor device of FIG. 13A at a subsequent stage of the fabrication process and taken along the X1-X2 line shown in FIG. 1C, according to embodiments.

FIG. 14B is a cross-sectional view of a semiconductor device of FIG. 13B at a subsequent stage of the fabrication process and taken along the Y1-Y2 line shown in FIG. 1C, according to embodiments.

FIG. 15A is a cross-sectional view of a semiconductor device of FIG. 14A at a subsequent stage of the fabrication process and taken along the X1-X2 line shown in FIG. 1C, according to embodiments.

FIG. 15B is a cross-sectional view of a semiconductor device of FIG. 14B at a subsequent stage of the fabrication process and taken along the Y1-Y2 line shown in FIG. 1C, according to embodiments.

FIG. 16A is a cross-sectional view of a semiconductor device of FIG. 15A at a according to embodiments.

FIG. 16B is a cross-sectional view of a semiconductor device of FIG. 15B at a according to embodiments.

FIG. 17A is a cross-sectional view of a semiconductor device of FIG. 16A at a subsequent stage of the fabrication process and taken along the X1-X2 line shown in FIG. 1C, according to embodiments.

FIG. 17B is a cross-sectional view of a semiconductor device of FIG. 16B at a subsequent stage of the fabrication process and taken along the Y1-Y2 line shown in FIG. 1C, according to embodiments.

FIG. 18A is a cross-sectional view of a semiconductor device of FIG. 17A at a subsequent stage of the fabrication process and taken along the X1-X2 line shown in FIG. 1C, according to embodiments.

FIG. 18B is a cross-sectional view of a semiconductor device of FIG. 17B at a subsequent stage of the fabrication process and taken along the Y1-Y2 line shown in FIG. 1C, according to embodiments.

FIG. 19A is a cross-sectional view of a semiconductor device of FIG. 18A at a subsequent stage of the fabrication process and taken along the X1-X2 line shown in FIG. 1C, according to embodiments.

FIG. 19B is a cross-sectional view of a semiconductor device of FIG. 18B at a subsequent stage of the fabrication process and taken along the Y1-Y2 line shown in FIG. 1C, according to embodiments.

FIG. 20A is a cross-sectional view of a semiconductor device of FIG. 19A at a according to embodiments.

FIG. 20B is a cross-sectional view of a semiconductor device of FIG. 19B at a according to embodiments.

FIG. 21A is a cross-sectional view of a semiconductor device of FIG. 20A at a subsequent stage of the fabrication process and taken along the X1-X2 line shown in FIG. 1C, according to embodiments.

FIG. 21B is a cross-sectional view of a semiconductor device of FIG. 20B at a subsequent stage of the fabrication process and taken along the Y1-Y2 line shown in FIG. 1C, according to embodiments.

### DETAILED DESCRIPTION

The present disclosure describes a semiconductor device. In particular, the present disclosure described semiconductor devices including a nanosheet stack disposed on a substrate. The semiconductor device also includes a source/drain epitaxial layer disposed on the substrate adjacent to the nanosheet stack. The semiconductor device also includes a source/drain contact formed in contact with the source/drain epitaxial layer. The source/drain contact includes a wrap-around portion that wraps around sidewall surfaces of the source/drain epitaxial layer, and an extending portion that extends from the wrap-around portion, where the wrap-around portion has a non-uniform thickness. Having a source/drain contact with a non-uniform thickness may allow for having a greater metal thickness toward a main contact side that allows for more efficient delivery of current to the source/drain epitaxial layers. Also, by having a relatively lower metal thickness toward the side opposite to where the contact connects to the BEOL or BSPDN, the lesser volume of metal can reduce the capacitance in that region between the contact (also referred to as CA) and the gate electrode. Thus, the present embodiments may allow for an overall capacitance decrease benefit due to the thinner portion without incurring a resistance penalty due to the thicker portion.

The flowcharts and cross-sectional diagrams in the Figures illustrate methods of manufacturing stacked FET devices according to various embodiments. In some alternative implementations, the manufacturing steps may occur in a different order that that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to” or “etching selectivity” such as, for example, “a first element selective to a second element” or “a first element having etching selectivity relative to a second element” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

In general, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA configuration, a nanosheet-based FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior channel electrostatics control, which is necessary for continuously scaling gate lengths down to seven (7) nanometer CMOS technology and below.

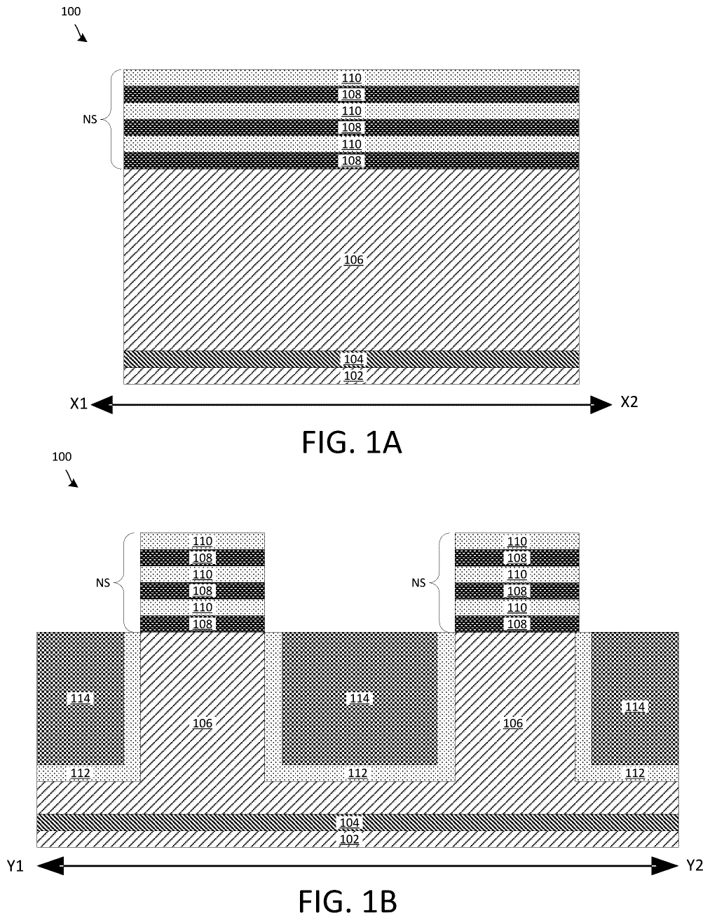

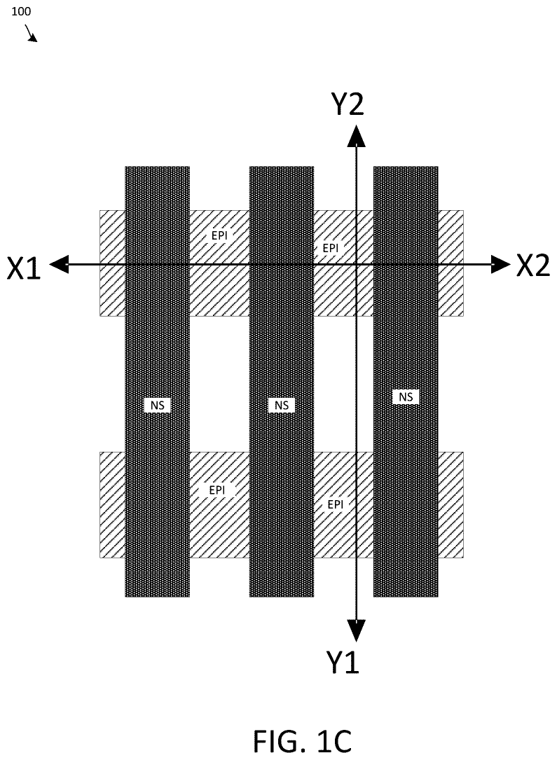

Referring now to the drawings in which like numerals represent the same or similar elements and initially to FIGS. 1A-1C, FIG. 1A depicts a cross-sectional view of a semiconductor device 100 at an intermediate stage of the manufacturing process and taken along the X1-X2 line shown in FIG. 1C. Thus, the X1-X2 line in FIG. 1A going from left to right corresponds to the X1-X2 line in FIG. 1C going from left to right. FIG. 1B depicts a cross-sectional view of the semiconductor device 100 taken along the Y1-Y2 line shown in FIG. 1C. Thus, the Y1-Y2 line in FIG. 1B going from left to right corresponds to the Y1-Y2 line in FIG. 1C going from bottom to top. FIG. 1C is a simplified top-down view of the semiconductor device 100 shown in FIGS. 1A and 1B, showing the general locations of the gate all-around nanosheet structures (labelled as NS in FIG. 1C) and the epitaxial layers (labelled as EPI in FIG. 1C), and generally where these areas intersect from a top-down perspective, according to embodiments.

In particular, FIGS. 1A-1C illustrate the manufacturing process at a stage after forming nanosheet structures (also referred to as nanosheet stacks) that include alternating layers of semiconductor layers 110 and sacrificial layers 108, shallow trench isolation (STI) regions 114, and STI liner layers 112/113. As shown in FIGS. 1A and 1B, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. The substrate 102 may be comprised of any other suitable material(s) than those listed above.

As shown in FIGS. 1A and 1B, an etch stop layer 104 is formed on the substrate 102. The etch stop layer 104 may comprise, for example, one or more of epitaxial SiGe layers (or SiO₂ if the starting wafer is an silicon-on-insulator (SOI) wafer), or any other appropriate etch stop materials. A second substrate 106 is formed on the etch stop layer 104. The second substrate 106 may comprise silicon, and the materials of the second substrate 106 may be the same or different than the materials of the substrate 102.

As also shown in FIG. 1B In some embodiments, shallow trench isolation (STI) regions 114 may be formed into the second substrate 106. In general, shallow trench isolation is an integrated circuit feature which prevents electric current leakage between adjacent semiconductor device components. STI is generally used on CMOS process technology nodes of 250 nanometers and smaller. STI regions are created early during the semiconductor device fabrication process before transistors are formed. The key steps of the STI process involve etching a pattern of trenches in the silicon, depositing one or more dielectric materials (such as silicon dioxide) to fill the trenches, and removing the excess dielectric using a technique such as chemical-mechanical planarization. In certain embodiments, as shown in FIG. 1B, a first STI liner layer 112 may be formed between the second substrate 106 and the STI regions 114. The first STI liner layer 112 may comprise, for example, SiN.

Referring again to FIGS. 1A and 1B, the semiconductor device 100 includes a nanosheet-containing material stack NS. The nanosheet stack NS includes alternating layers of a sacrificial layer 108 and a semiconductor layer 110. Although the structure shown in FIGS. 1A and 1B is shown at a stage in the manufacturing process after the nanosheet stack NS has already been formed (for the sake of simplicity), one example process of forming these nanosheet stacks is described below. In this example, the nanosheet stack NS initially includes a sacrificial layer 108 that is formed on the second substrate 106, followed by the formation of a semiconductor layer 110. In an example, the sacrificial layer is composed of silicon-germanium (e.g., SiGe35, or more generally, where the Ge ranges from about 15-35%). In an example, the semiconductor layer 110 is composed of silicon. Several additional layers of the sacrificial layer 108 and the semiconductor layer 110 are alternately formed. It should be appreciated that any suitable number of alternating layers of sacrificial layers 108 and semiconductor layers 110 may be formed.

In certain embodiments, the sacrificial layers 108 have a vertical thickness ranging, for example, from approximately 3 nm to approximately 20 nm. In certain embodiments, the semiconductor layers 110 have a vertical thickness ranging, for example, from approximately 3 nanometers (nm) to approximately 10 nm. Although the range of 3-20 nm is cited as an example range of thickness, other thicknesses of these layers may be used. In certain examples, certain of the sacrificial layers 108 and/or the semiconductor layers 110 may have different thicknesses relative to one another. Therefore, multiple epitaxial growth processes can be performed to form the sacrificial layers 108 and the semiconductor layers 110. In certain embodiments, the sacrificial layers 108 and the semiconductor layers 110 may initially deposited over the entire surface of the semiconductor device 100, and then later patterned to form the structures shown in FIG. 1B.

In certain embodiments, it may be desirable to have a small vertical spacing between adjacent nanosheet layers in the nanosheet stack NS to reduce the parasitic capacitance and to improve circuit speed. For example, the VSP (the distance between the bottom surface of a first nanosheet layer and the top surface of an adjacent second nanosheet layer, where the second nanosheet layer is below the first nanosheet layer) may range from 5 nm to 15 nm. However, the VSP must be of a sufficient value to accommodate the gate stack that will be formed in the spaces created by later removal of the sacrificial layers.

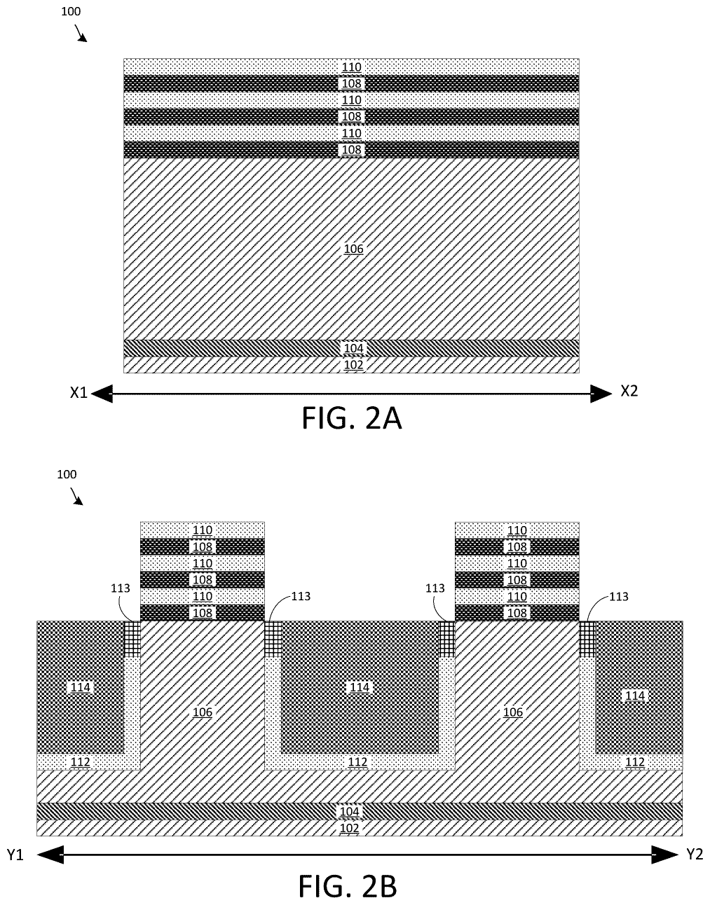

Referring now to FIGS. 2A and 2B, these figures are cross-sectional views of the semiconductor device of FIGS. 1A and 1B, respectively, at a subsequent stage of the fabrication process, according to embodiments. FIG. 2A is taken along the line X1-X2 from FIG. 1C, and FIG. 2B is taken along the line Y1-Y2 from FIG. 1C. As shown in FIG. 2B, a portion of the first STI liner layer 112 is removed with any suitable material removal process to form a recess therein. Then, a second STI liner layer 113 is deposited in these recesses. In certain examples, the second STI liner layer may comprise SiC or SiCO.

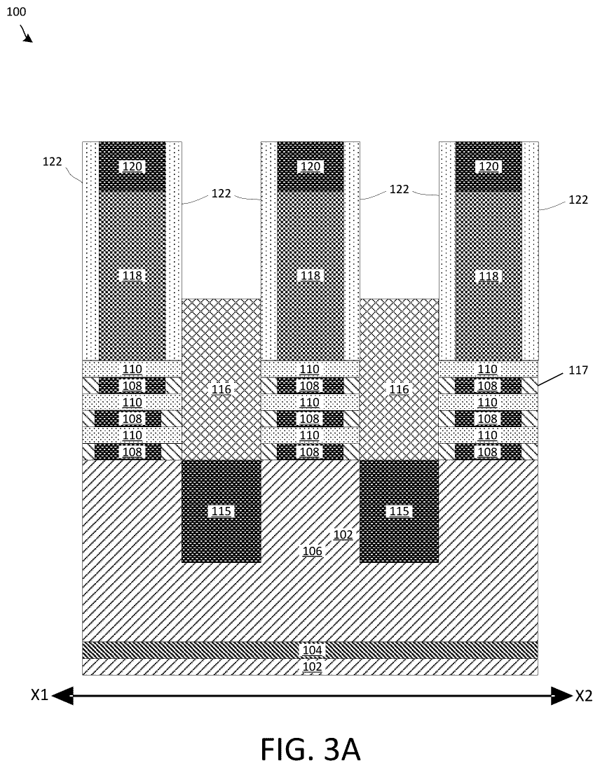

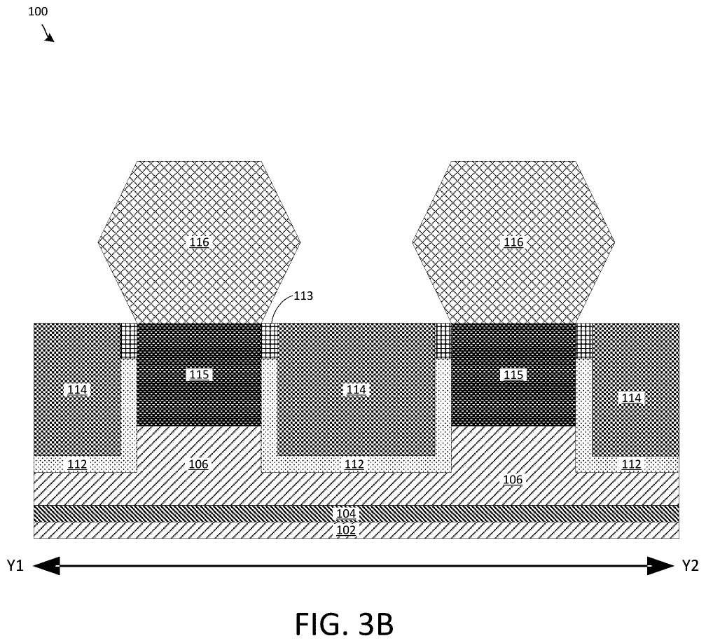

Referring now to FIGS. 3A and 3B, these figures are cross-sectional views of the semiconductor device of FIGS. 2A and 2B, respectively, at a subsequent stage of the fabrication process, according to embodiments. FIG. 3A is taken along the line X1-X2 from FIG. 1C, and FIG. 3B is taken along the line Y1-Y2 from FIG. 1C. It should be appreciated that several different processing operations have occurred between FIGS. 2A/2B and 3A/3B. As shown in FIGS. 3A and 3B, in certain examples, a dummy gate 118 (or dummy polycrystalline (PC) layer) is formed on the nanosheet stack NS. The dummy gate 118 may be formed by any suitable deposition technique known to one of skill in the art. In one example, the dummy gate 118 is formed by depositing a thin SiO₂ dummy gate oxide layer (not shown), followed by depositing a layer of amorphous silicon (a-Si) as the dummy gate 118. The dummy gate 118 may be composed of polycrystalline silicon (poly silicon), amorphous silicon, and/or an oxide, such as, SiO₂. Gate patterning may be performed by first patterning a gate hardmask (not shown) and then using the patterned gate hardmask to etch the dummy gates 118. After the dummy gate 118 is formed, a gate spacer 122 is formed on both sides of the dummy gate 118. The gate spacer 118 may comprise, for example, SiOC. After that, the sacrificial layers 108 of the nanosheet stack NS at the source/drain regions which are not protected by gate hardmask 120 and gate spacers 112 are recessed in a horizontal direction, followed by inner spacer 117 formation (only one labeled in FIG. 3A for clarity). The inner spacers 117 may comprise, for example, SiOC. A selective etching process using, for example, a boron-based chemistry or a chlorine-based chemistry may be used, which selectively recesses the exposed portions of the sacrificial layers 108 without significantly attacking the surrounding materials. Then, the inner spacers 117 are formed in the indents created by the removal of these portions of the sacrificial layers 108. An isotropic etching process may be performed to clean up the edges of the inner spacers 117 and the semiconductor layers 110.

As shown in FIGS. 3A and 3B, recesses (not shown) are formed into the second substrate 106, followed by SiGe indentation and inner spacer 117 formation, and then a source/drain (S/D) placeholder layer 115 is formed into these recesses. In certain embodiments, the source/drain placeholder layer 115 may comprise SiGe. It should be appreciated that the S/D placeholder layer 115 may not contribute to the functionality of the device, but it may be used as a sacrificial layer (i.e., to be eventually removed), and it may be used to facilitate the manufacture of the semiconductor device, as discussed in detail below. Then, as shown in FIG. 3A, S/D epitaxial layers 116 are formed on the source/drain placeholder layer 115 and between the nanosheet stacks NS. In certain embodiments, the S/D epitaxial layers 116 are formed to a height that is greater than a height of the nanosheet stacks NS. As shown in FIG. 3B, in certain embodiments, the S/D epitaxial layers 116 may be wider than the S/D placeholder layer 115, but they do not cover up the second STI liner layer 113. Also, in certain embodiments, the S/D epitaxial layers 116 have a generally hexagonal shape as shown in the cross-sectional view of FIG. 3B.

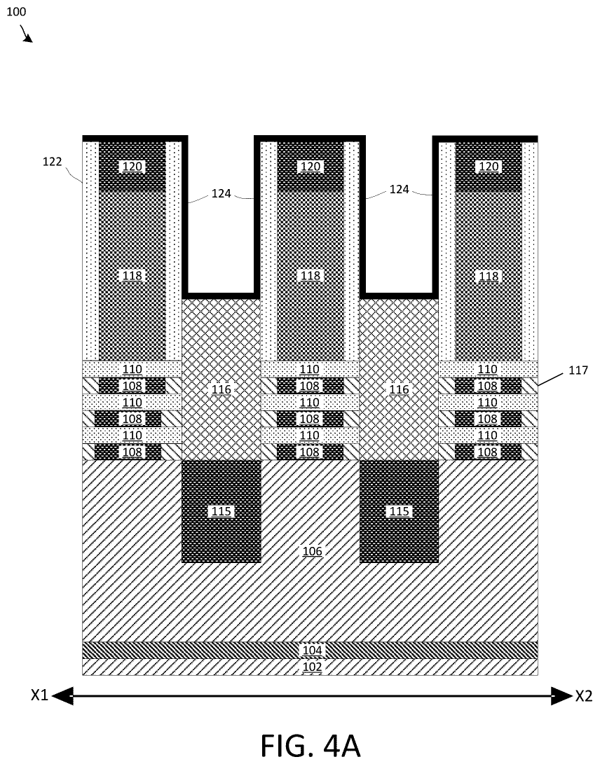

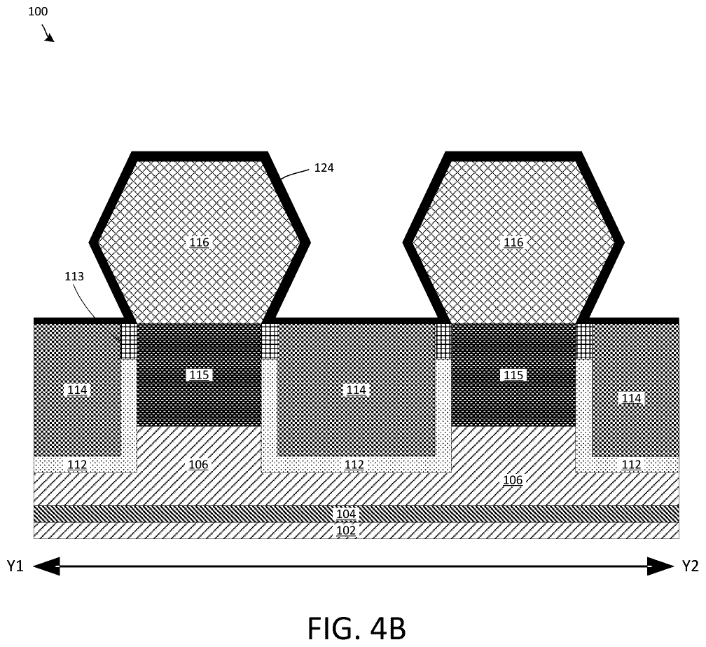

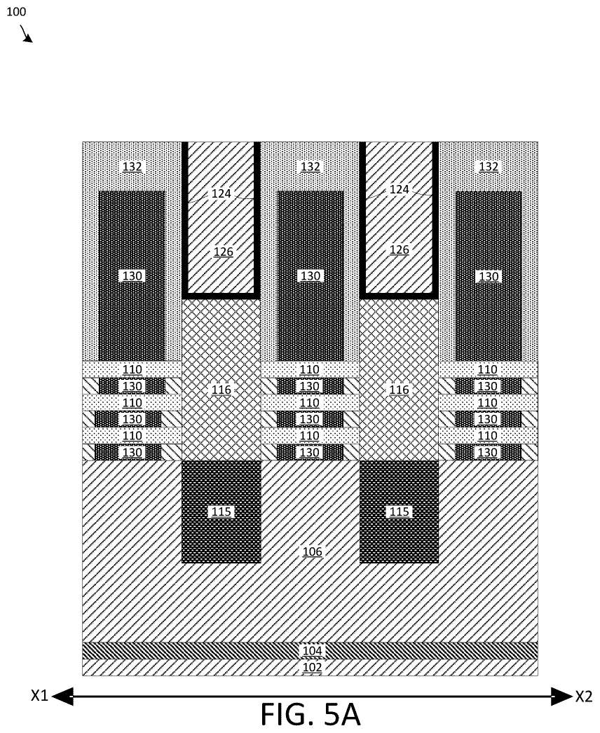

Referring now to FIGS. 4A and 4B, these figures are cross-sectional views of the semiconductor device of FIGS. 3A and 3B, respectively, at a subsequent stage of the fabrication process, according to embodiments. FIG. 4A is taken along the line X1-X2 from FIG. 1C, and FIG. 4B is taken along the line Y1-Y2 from FIG. 1C. As shown in FIGS. 4A and 4B, a liner layer 124 is formed (e.g., by a conformal material deposition process) on the S/D epitaxial layers 116, the sidewalls of the gate spacer 112, and on top of the hard mask 120. As shown in FIG. 4B, the liner layer 124 is also formed to cover the second STI liner layer 113 and the STI regions 114. In certain embodiments, the liner layer 124 may comprise, for example, SiN.

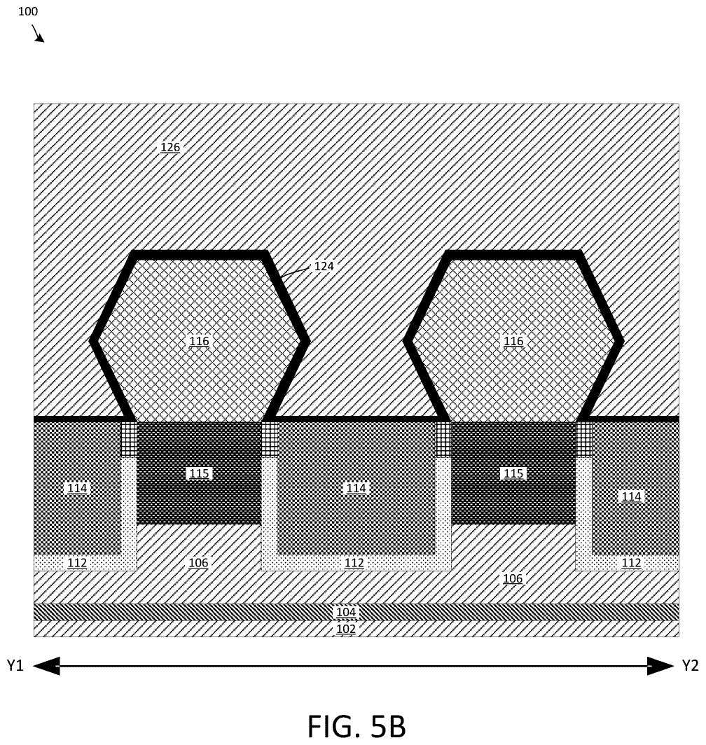

Referring now to FIGS. 5A and 5B, these figures are cross-sectional views of the semiconductor device of FIGS. 4A and 4B, respectively, at a subsequent stage of the fabrication process, according to embodiments. FIG. 5A is taken along the line X1-X2 from FIG. 1C, and FIG. 5B is taken along the line Y1-Y2 from FIG. 1C. It should be appreciated that several different processing operations have occurred between FIGS. 4A/4B and 5A/5B. In certain embodiments, although not shown in FIGS. 5A and 5B, ILD 126 is deposited, followed by CMP to expose the dummy gate or gate hardmask, and a gate cut patterning process is performed to etch away the dummy gate 118 in a gate cut region, followed by filling the gate cut region with dielectric material (not shown). Then, the dummy gate 118 is selectively removed, followed by removal of (or release of) the SiGe material of the sacrificial layers 108. After the material of the sacrificial layers 108 has been released, a high-K metal gate (HKMG) dielectric layer (not shown) and a gate electrode 130 (i.e., that includes a work function metal (WFM)) are formed in the spaces created by the removal of the SiGe material of the sacrificial layers 110. In certain examples, the forming of the gate electrode 130 structure includes forming a continuous layer of gate dielectric material and a gate electrode material inside the gate opening. The continuous layer of gate dielectric material can include silicon oxide, or a dielectric material having a dielectric constant greater than 4.0 (such dielectric materials can be referred to as a high-K metal gate dielectric material). Illustrative examples of high-k gate dielectric materials include metal oxides such as, for example, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The HKMG dielectric layer dielectric material can further include dopants such as lanthanum (La), aluminum (Al) and/or magnesium (Mg). The continuous layer of the high-k metal gate can be formed utilizing a deposition process such as, for example, ALD, CVD, PECVD, or PVD. The continuous layer of the HKMG dielectric layer is a conformal layer having a thickness which can range from 1 nm to 10 nm.

After this, an NFET or PFET work function metal (WFM) layer is deposited in the spaces created by the previous removal of the sacrificial layers 108 in the nanosheet stack NS to form the gate electrode 130 structure. The different WFM layers form the gate electrode 130 structures. The WFM layers can be used to set a threshold voltage of the FET to a desired value. In some embodiments, the layer of WFM can be selected to effectuate an n-type threshold voltage shift. “N-type threshold voltage shift” as used herein means a shift in the effective work-function of the work-function metal-containing material towards a conduction band of silicon in a silicon-containing material. In solid-state physics, the work function is the minimum thermodynamic work (i.e., energy) needed to remove an electron from a solid to a point in the vacuum immediately outside the solid surface. Also, this energy (work function) is a measure of how firmly a particular metal holds its electrons. In general, the conduction band is the range of permissible energy values which an electron in a solid material can have that allows the electron to dissociate from a particular atom and become a free charge carrier in the material. In one embodiment, the work function of the n-type work function metal ranges from approximately 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the layer of WFM can be selected to effectuate a p-type threshold voltage shift. In one embodiment, the work function of the p-type work function metal ranges from approximately 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. In general, the valence band is the range of permissible energy values that are the highest energies an electron can have and still be associated with a particular atom of a solid material. Examples of such materials that can effectuate a p-type threshold voltage shift include, but are not limited to, titanium nitride, and tantalum carbide, hafnium carbide, and combinations thereof. The layers of WFM are conformal layers which can be formed by a conformal deposition process such as, for example, ALD, CVD or PECVD. The layer of WFM layer can have a thickness in the range of approximately 1 nm to 20 nm, although other thicknesses above or below this range may be used as desired for a particular application. In the embodiment shown in FIGS. 5A and 5B, the NFET or PFET work function metal (WFM) layers that form the gate electrode 130 structure are deposited in the spaces created by the previous removal of the sacrificial layers 108 in the nanosheet stack NS.

As shown in FIGS. 5A and 5B, a first interlayer dielectric (ILD) layer 126 is deposited into the spaces above and around the S/D epitaxial layers 116. The ILD layer 126 may comprise any suitable dielectric material, such as an oxide-based material. Then, in certain embodiments, after deposition of the ILD layer 126 a suitable material removal process, such as CMP, is used to planarize the upper surface of the semiconductor device 100 and remove portions of the liner layer 124 on the top surfaces of the hard mask 120. Then, further processing is performed to remove the hard mask 120, the gate spacers 112, the dummy gate 118, and the sacrificial layers 108, and replace them with a suitable combination of NFET WFM layers and PFET WFM layers to form the gate electrode 130 structure. FIG. 5A shows a configuration of the semiconductor device 100 after the sacrificial layers 108 and dummy gate 118 have been removed and the WFM layers have been added for the gate electrode 130. Then, a gate cap 132 is formed on the sides and top of the gate electrode 130. In certain embodiments, the gate cap 132 may comprise SiOC.

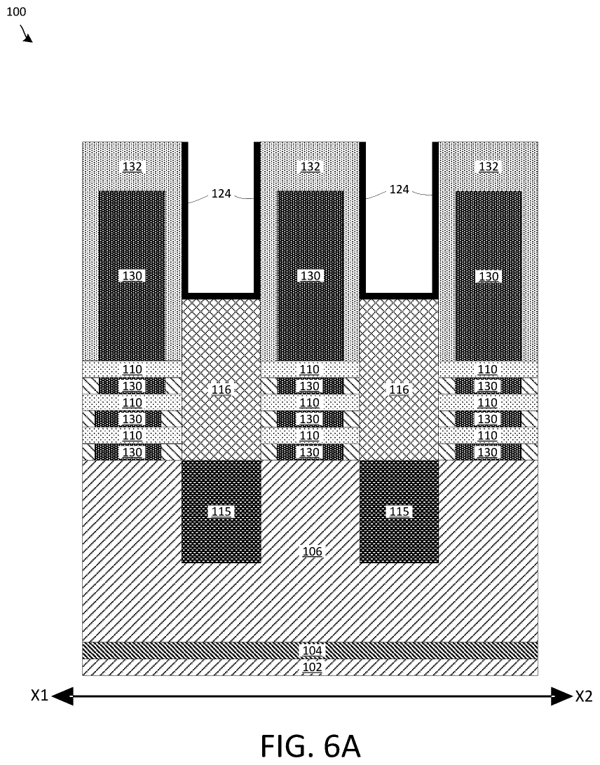

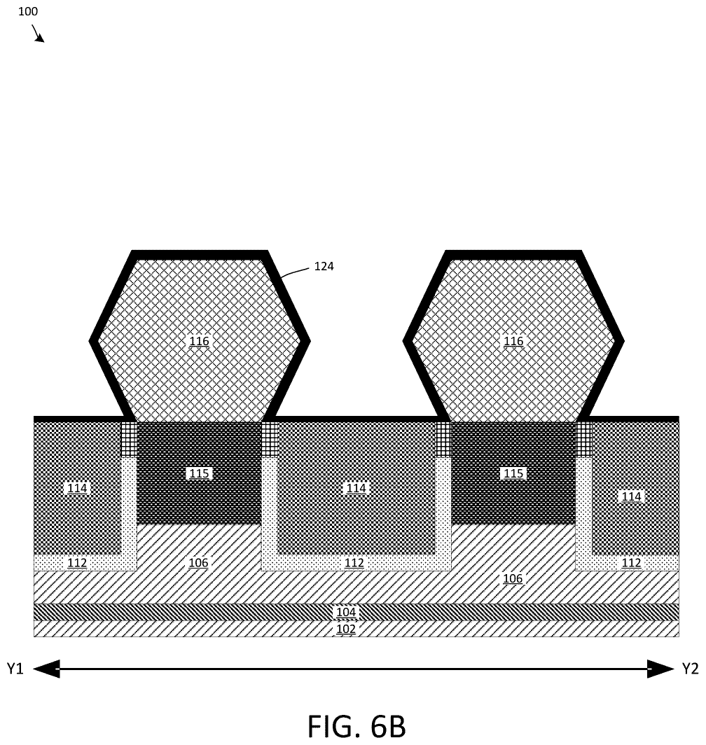

Referring now to FIGS. 6A and 6B, these figures are cross-sectional views of the semiconductor device of FIGS. 5A and 5B, respectively, at a subsequent stage of the fabrication process, according to embodiments. FIG. 6A is taken along the line X1-X2 from FIG. 1C, and FIG. 6B is taken along the line Y1-Y2 from FIG. 1C. As shown in FIGS. 6A and 6B, a suitable material removal process is used to remove the ILD layer 126. In this process, a suitable etching process may be used that has selectivity for the material of the ILD layer 126 (e.g., an oxide material) relative to the material of the liner layer 124 (e.g., SiN) and the material of the gate cap 132 (e.g., SiOC). In this way, the material of the ILD layer 126 can be removed without removing significant portions of either the liner layer 124 or the gate cap 132.

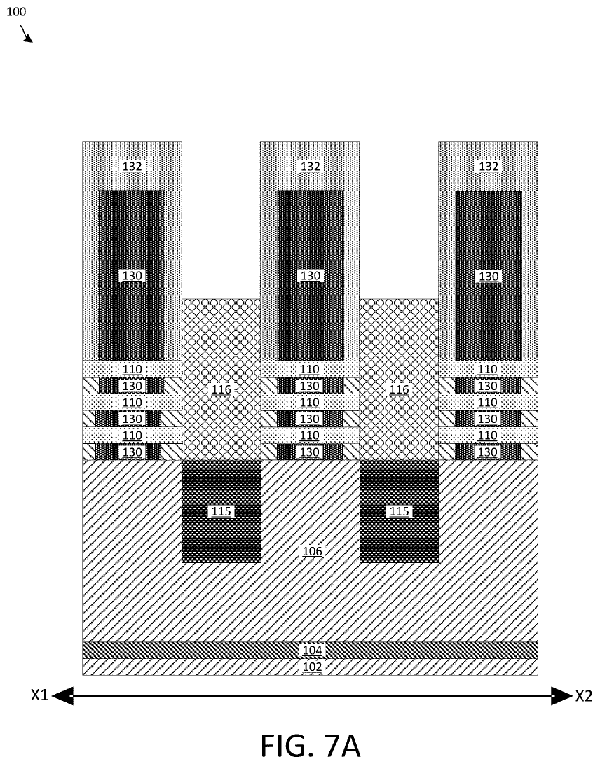

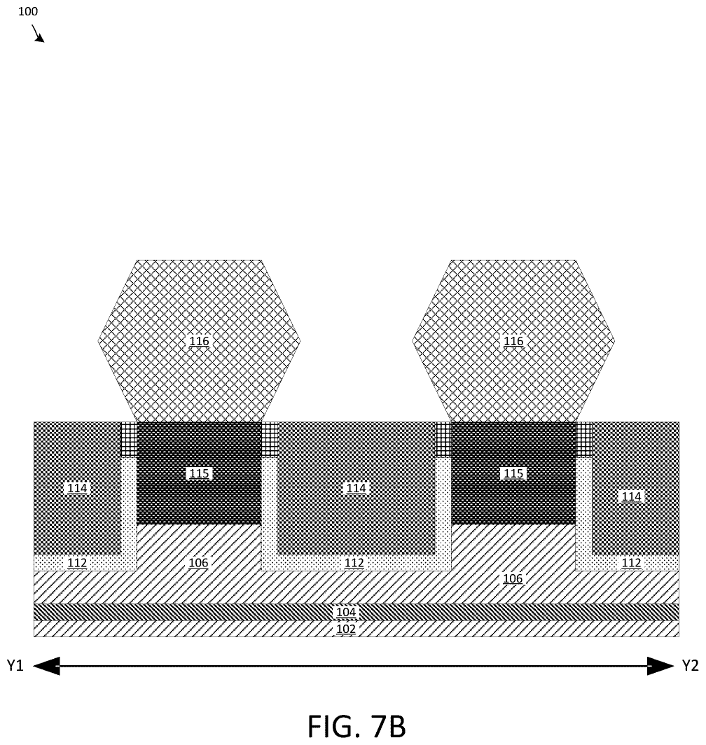

Referring now to FIGS. 7A and 7B, these figures are cross-sectional views of the semiconductor device of FIGS. 6A and 6B, respectively, at a subsequent stage of the fabrication process, according to embodiments. FIG. 7A is taken along the line X1-X2 from FIG. 1C, and FIG. 7B is taken along the line Y1-Y2 from FIG. 1C. As shown in FIGS. 7A and 7B, a suitable material removal process is used to remove the liner layer 124. In this process, a suitable etching process may be used that has selectivity for the material of the liner layer 124 (e.g., SiN) relative to the material of the gate cap 132 (e.g., SiOC). In this way, the material of the liner layer 124 can be removed without removing significant portions of the gate cap 132.

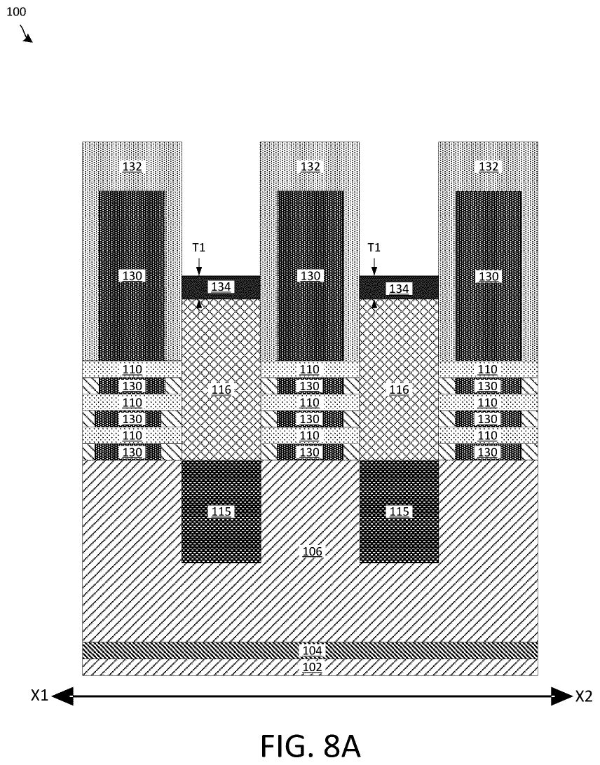

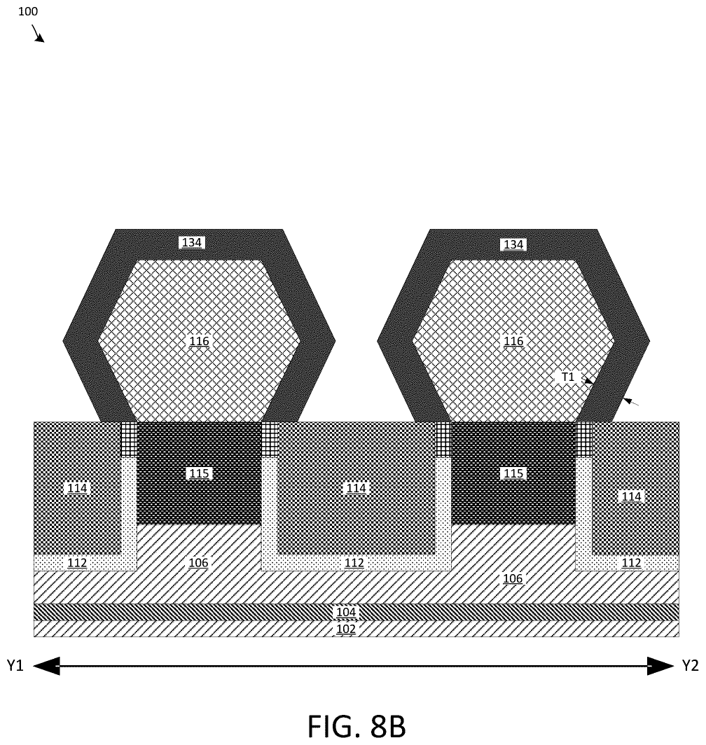

Referring now to FIGS. 8A and 8B, these figures are cross-sectional views of the semiconductor device of FIGS. 7A and 7B, respectively, at a subsequent stage of the fabrication process, according to embodiments. FIG. 8A is taken along the line X1-X2 from FIG. 1C, and FIG. 8B is taken along the line Y1-Y2 from FIG. 1C. As shown in FIGS. 8A and 8B, a second epitaxial layer 134 is formed on the exposed surfaces of the S/D epitaxial layers 116. In certain embodiments, the second epitaxial layer 134 comprises, for example, Ge or a high Ge % SiGe material (e.g., high Ge % is about 50% or higher). It should be appreciated that materials with a high Ge % SiGe may not be as stable during a high temperature annealing process (e.g., such as high-K PDA or a high-K reliability anneal). However, at this stage of the manufacturing process, high temperature annealing may no longer be required in subsequent operations, so it is acceptable to form the high Ge % SiGe material without risk of diminishing the quality of this second epitaxial layer 134. As shown in FIG. 8B, the second epitaxial layer 134 is grown to an initial uniform thickness of T1. As will be described in further detail below, the second epitaxial layer 134 is a sacrificial layer that will later be removed to allow for subsequent formation of the metal S/D contacts.

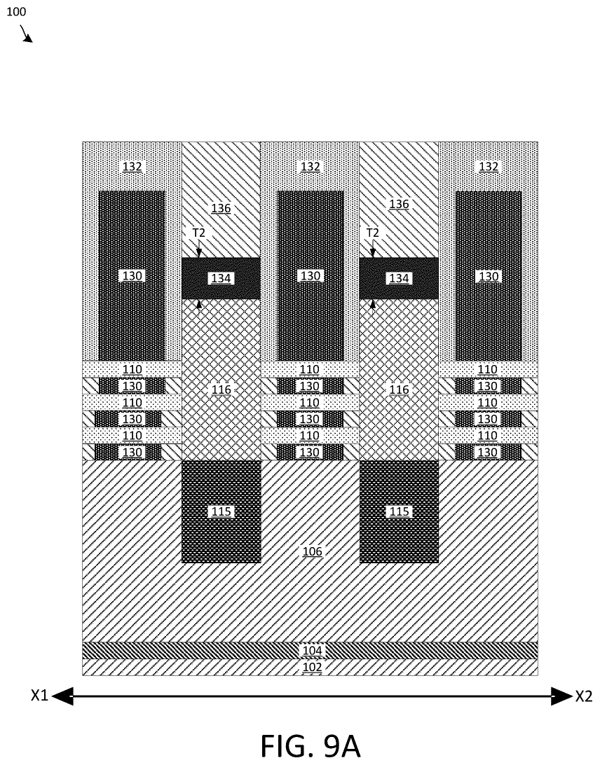

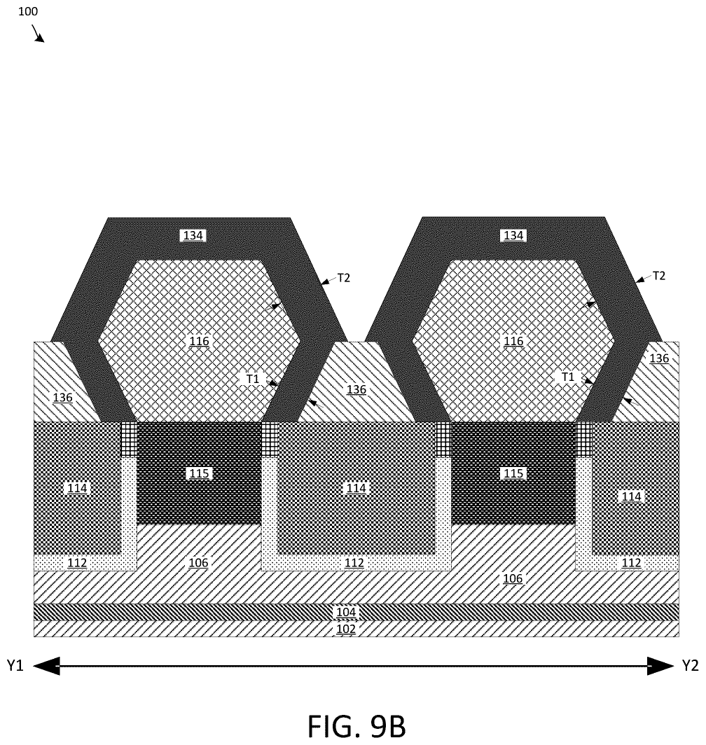

Referring now to FIGS. 9A and 9B, these figures are cross-sectional views of the semiconductor device of FIGS. 8A and 8B, respectively, at a subsequent stage of the fabrication process, according to embodiments. FIG. 9A is taken along the line X1-X2 from FIG. 9C, and FIG. 2B is taken along the line Y1-Y2 from FIG. 1C. As shown in cross-sectional view of FIG. 9B, a second ILD layer 136 is formed on the second epitaxial layer 134 and between the gate caps 132. It is to be noted that at this stage, the material of the second ILD layer 136 is not yet added to the top of the second epitaxial layer 134 when viewed along the X1-X2 line in the cross-sectional view of FIG. 9A (it will be added after the additional material of the second epitaxial layer 134 is added as discussed next). As shown in the cross-sectional view of FIG. 9B, the second ILD layer 136 is formed around the S/D epitaxial layers 116 to a level that generally corresponds to a middle of the S/D epitaxial layers 116. It should be appreciated that, in certain embodiments, the level of the second ILD layer 136 may be somewhat above or below the exact middle of the S/D epitaxial layers 116. In certain embodiments, the second ILD layer 136 may initially be formed to a higher level than that shown in FIG. 9B (i.e., to the higher level shown in FIG. 9A), and then a material removal process is employed to recess (or lower the height of) the second ILD layer 136 to the level shown in FIG. 9B. Then, additional material of the second epitaxial layer 134 is deposited to increase the thickness of the exposed upper half of the S/D epitaxial layers 116 from T1 to T2 (i.e., T2>T1), as shown in FIG. 9B. Also, as shown in FIG. 9A, the additional material of the second epitaxial layer 134 is deposited to increase the thickness from T1 to T2.

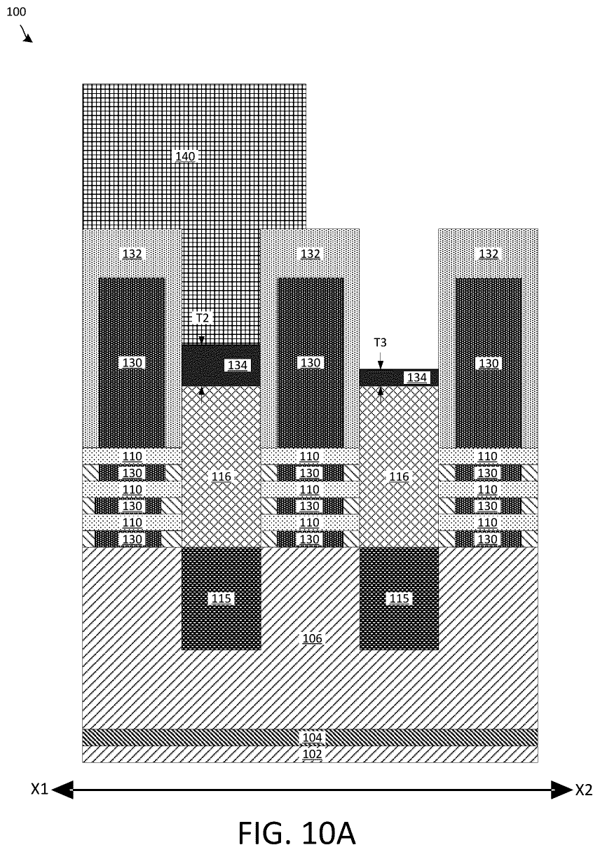

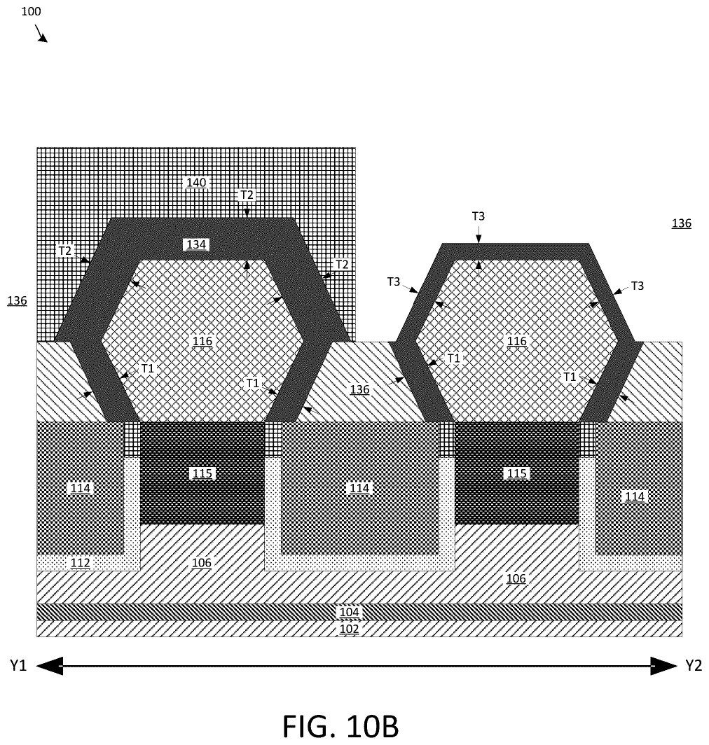

Referring now to FIGS. 10A and 10B, these figures are cross-sectional views of the semiconductor device of FIGS. 9A and 9B, respectively, at a subsequent stage of the fabrication process, according to embodiments. FIG. 10A is taken along the line X1-X2 from FIG. 1C, and FIG. 10B is taken along the line Y1-Y2 from FIG. 1C. As shown in FIGS. 10A and 10B, an organic planarization (OPL) layer 140 is formed. In the view of FIG. 10A, the OPL layer 140 is formed to cover at least the left second epitaxial region 134 (i.e., on the X1 side). In the view of FIG. 10B, the OPL layer 140 is formed to cover at least the left S/D epitaxial region 116 (i.e., on the Y1 side) and the left second epitaxial region 134. Then, a suitable material removal process is used to remove a portion of the right second epitaxial layer 134 to a thickness of T3, where T3<T1<T2. Thus, as shown in FIG. 9B, the left second epitaxial layer 134 (i.e., on the Y1 side) has an upper portion with a thickness of T2 and a lower portion with a thickness of T1. Also, as shown in FIG. 10B, the right second epitaxial layer 134 (i.e., on the Y2 side) has an upper portion with a thickness of T3 and a lower portion with a thickness of T1. When viewed in FIG. 10A, the left second epitaxial layer 134 (i.e., on the X1 side) has a thickness of T2, and the right second epitaxial layer 134 (i.e., on the X2 side) has a thickness of T3.

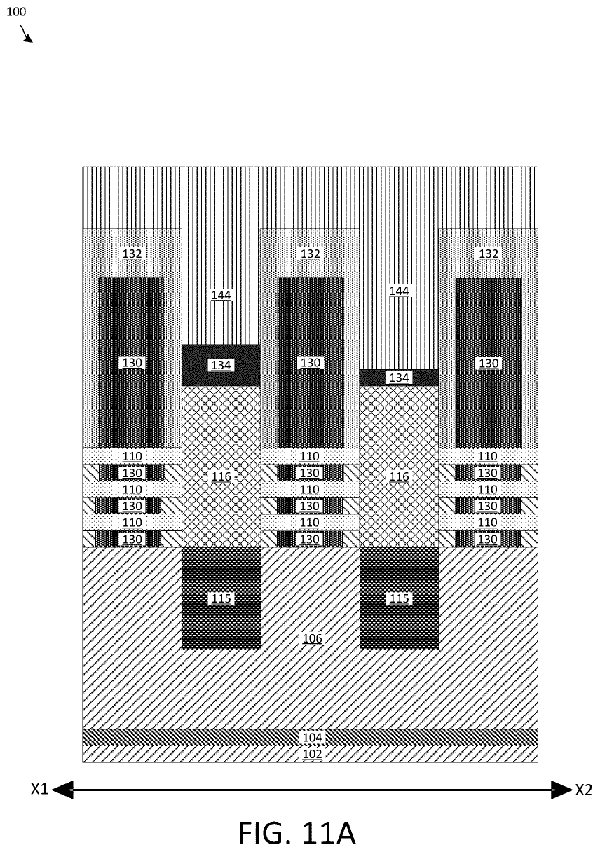

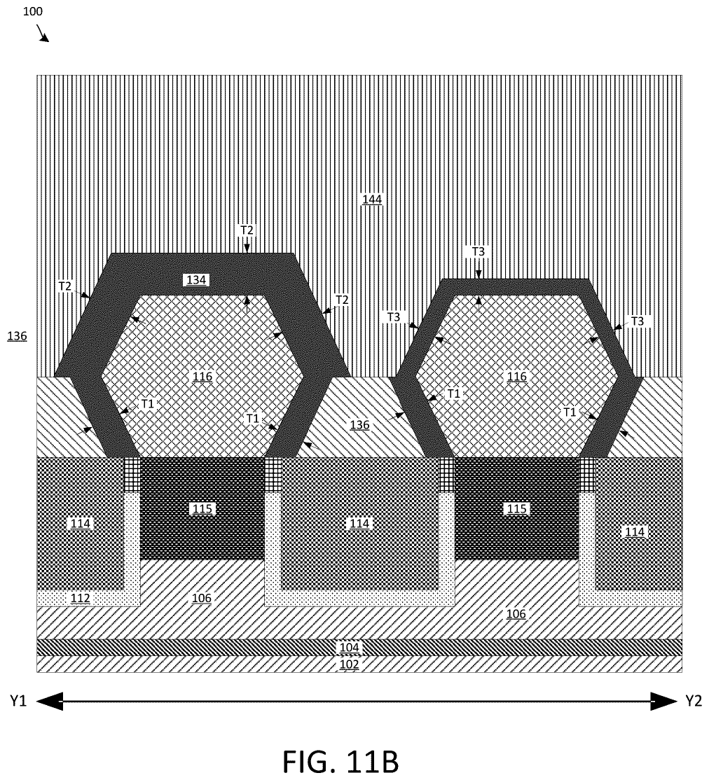

Referring now to FIGS. 11A and 11B, these figures are cross-sectional views of the semiconductor device of FIGS. 10A and 10B, respectively, at a subsequent stage of the fabrication process, according to embodiments. FIG. 11A is taken along the line X1-X2 from FIG. 1C, and FIG. 11B is taken along the line Y1-Y2 from FIG. 1C. As shown in FIGS. 11A and 11B, a suitable material removal process is performed to remove the OPL layer 140, and then a third ILD layer 144 is deposited on the second ILD layer 136 (as seen in FIG. 11B) and on the second epitaxial layer 134 (as seen in both FIGS. 11A and 11B). In certain embodiments, CMP may be performed to planarize the surface of the third ILD layer 144.

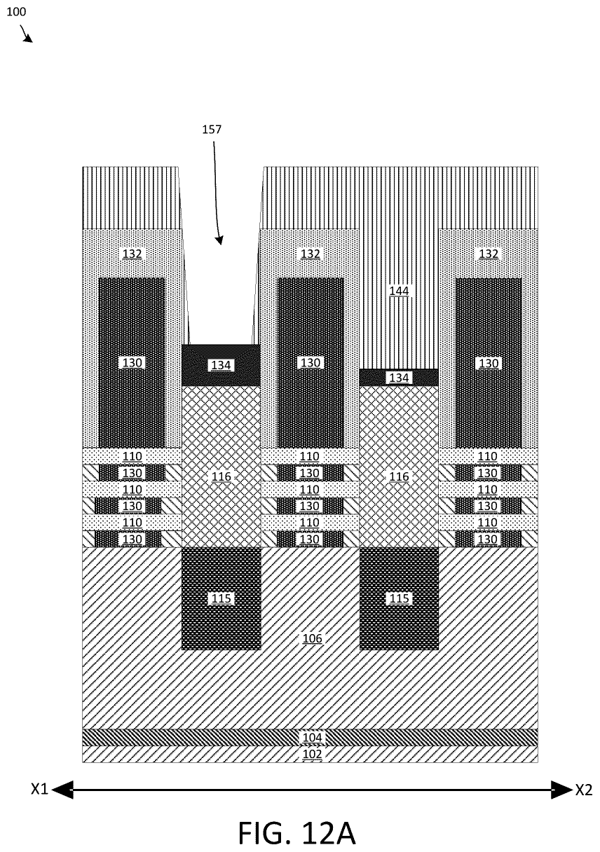

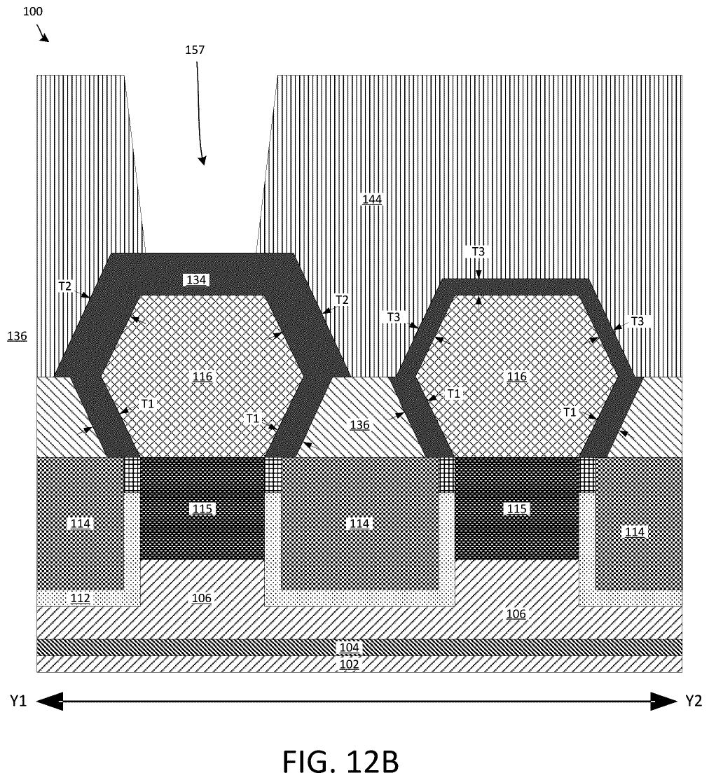

Referring now to FIGS. 12A and 12B, these figures are cross-sectional views of the semiconductor device of FIGS. 11A and 11B, respectively, at a subsequent stage of the fabrication process, according to embodiments. FIG. 12A is taken along the line X1-X2 from FIG. 1C, and FIG. 12B is taken along the line Y1-Y2 from FIG. 1C. As shown in FIG. 12A, a suitable material removal process is performed to remove a portion of the third ILD layer 144 and form a middle of line (MOL) contact opening 157 to expose the left side second epitaxial layer 134 (i.e., on the X1 side of FIG. 12A). As shown in FIG. 12B, the material removal process also forms a middle of line (MOL) contact opening 157 in the third ILD layer 144 to expose the left side second epitaxial layer 134 (i.e., on the Y1 side of FIG. 12B).

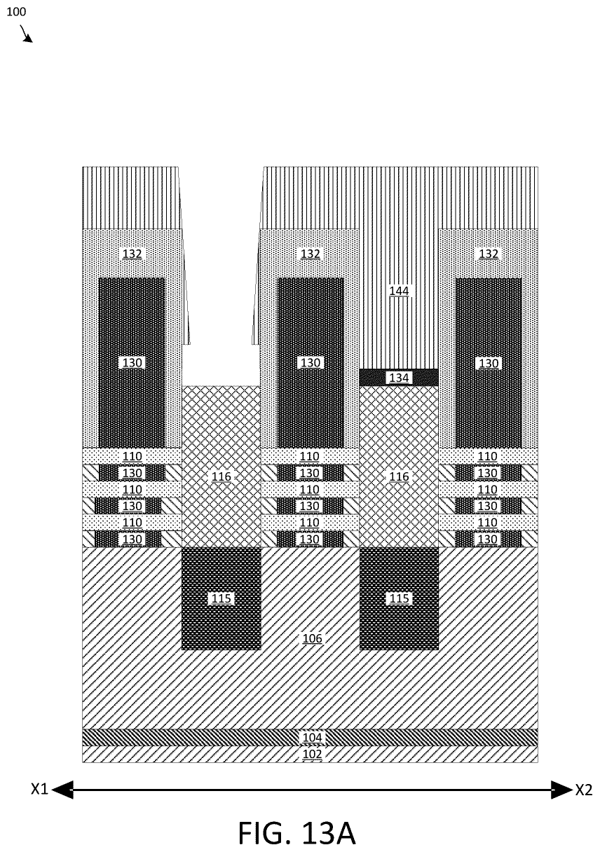

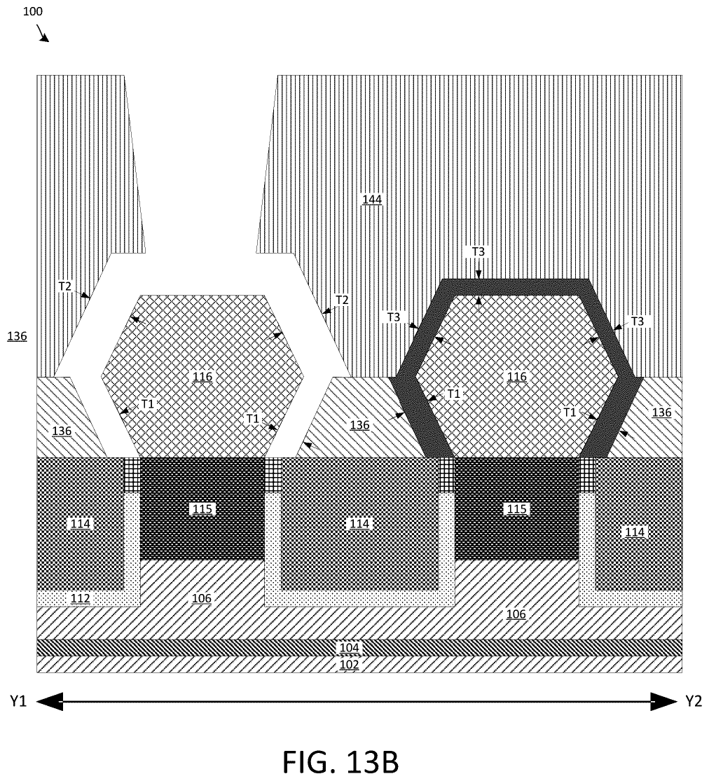

Referring now to FIGS. 13A and 13B, these figures are cross-sectional views of the semiconductor device of FIGS. 12A and 12B, respectively, at a subsequent stage of the fabrication process, according to embodiments. FIG. 13A is taken along the line X1-X2 from FIG. 1C, and FIG. 13B is taken along the line Y1-Y2 from FIG. 1C. As shown in FIG. 13A, a suitable material removal process is performed to remove the sacrificial material of the left side second epitaxial layer 134 (i.e., on the X1 side). As shown in FIG. 13B, the material removal process also removes the sacrificial material of the left side second epitaxial layer 134 (i.e., on the Y1 side). The material removal process may be, for example, a wet etching process. The removal of this sacrificial material of the left side second epitaxial layer 134 creates an opening, as seen in FIG. 13B, that extends around the left side S/D epitaxial layer 116 to allow for the subsequent formation of the wrap around metallization contacts. It should be appreciated that a suitable etchant may be chosen that selectively removes the second epitaxial layer 134 without significantly affecting the third ILD layer 144, the S/D epitaxial layer 116, the second ILD layer 136, the second STI liner layer 113 or the STI regions 114.

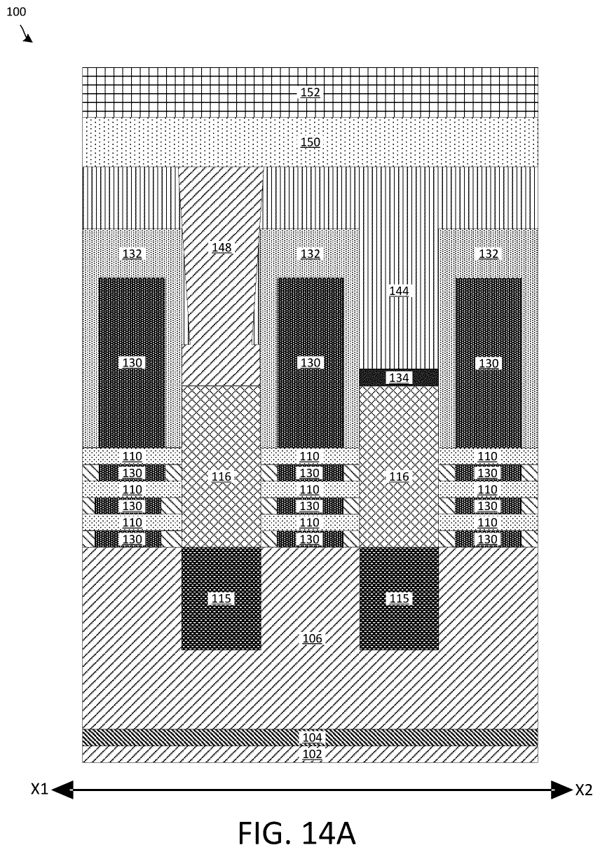

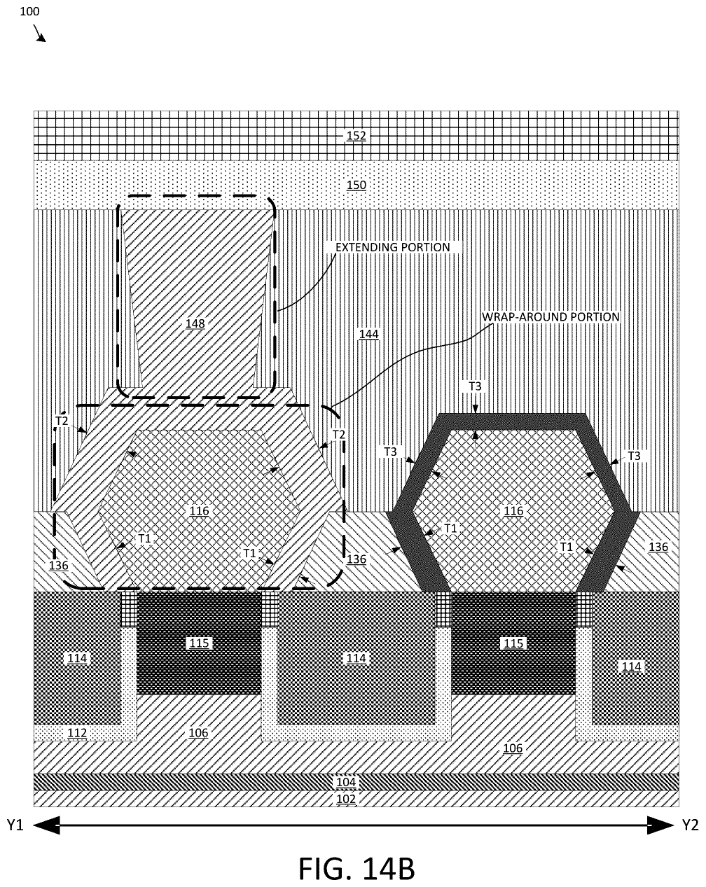

Referring now to FIGS. 14A and 14B, these figures are cross-sectional views of the semiconductor device of FIGS. 13A and 13B, respectively, at a subsequent stage of the fabrication process, according to embodiments. FIG. 14A is taken along the line X1-X2 from FIG. 1C, and FIG. 14B is taken along the line Y1-Y2 from FIG. 1C. As shown in FIG. 14A, a MOL contact metallization 148 (or more generally a source/drain contact) is formed to fill in the MOL contact opening 157. It should be appreciated that the term “source/drain contact” as used herein refers more generally to a metallic contact that connects the source/drain epitaxial layer to a power source, regardless of whether such source/drain contact metallization is electrically routed to a BEOL layer or a BSPDN. As shown in FIG. 14B, the MOL contact metallization 148 also fills in the MOL contact opening 157 and also fills in the spaces to wrap around the left side S/D epitaxial layer 116 (i.e., on the Y1 side). The portion of the MOL contact metallization 148 that wraps around the source/drain epitaxial layer 116 is referred to herein as a “wrap-around portion,” and this generally refers to the parts of the contact metallization that wrap around and cover at least some of the sidewall surfaces of the respective source/drain epitaxial layer 116. This generally region is indicated by a dashed area in FIG. 14B. The portion of the MOL contact metallization 148 that extends upwardly from the source/drain epitaxial layer 116 is referred to herein as an “extending portion,” and this term more generally refers to the part of the contact metallization that extends away from the “wrap-around portion” to electrically connect to a power source. This generally region is indicated by a dashed area in FIG. 14B. It should be appreciated that the wrap-around portion and the extending portion of the contact metallizations may be formed in a single processing step and may comprise the same material, and distinguishing between these two portions is for ease of understanding with regarding to which portions of the contact metallizations have the differing thicknesses. As used herein, the term “non-uniform thickness” as applied to the wrap-around portion indicates that there is at least one part of the wrap-around portion having a first thickness and another part having a different thickness.

As shown in FIG. 14B, the resulting MOL contact metallization 148 for the left side S/D epitaxial layer 116 has a lower half portion (also referred to herein as a first or second section of the wrap-around portion of the source/drain contact) with a thickness of T1 and an upper half portion (also referred to herein as a second or first section of the wrap-around portion of the source/drain contact) with a thickness of T2, where T2>T1. Then, as shown in both FIGS. 14A and 14B, a back end of line (BEOL) layer 150 is formed on top of the MOL contact metallization 148 an on top of the third ILD layer 144. After formation of the BEOL layer 150, a carrier wafer is formed on (or attached to) the BEOL layer 150.

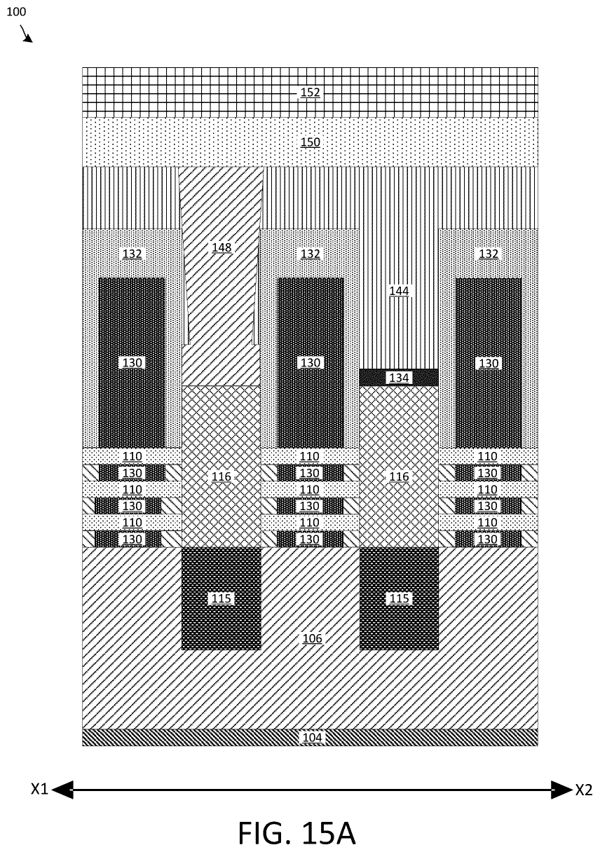

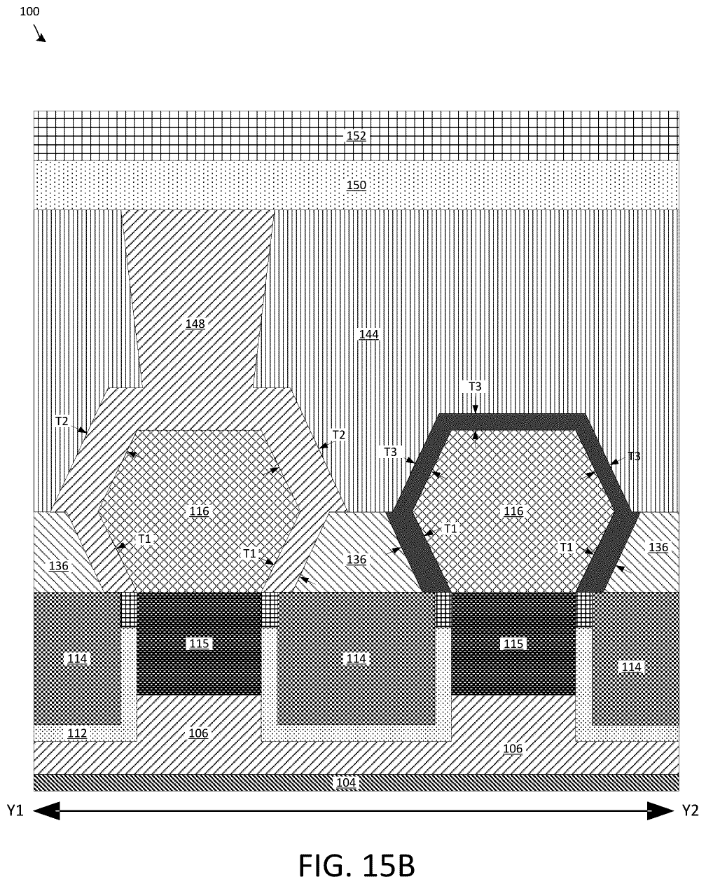

Referring now to FIGS. 15A and 15B, these figures are cross-sectional views of the semiconductor device of FIGS. 14A and 14B, respectively, at a subsequent stage of the fabrication process, according to embodiments. FIG. 15A is taken along the line X1-X2 from FIG. 1C, and FIG. 15B is taken along the line Y1-Y2 from FIG. 1C. As shown in FIGS. 15A and 15B, a suitable material removal process such as grinding or CMP is performed to remove the substrate 102, using the etch stop layer 104 as a stopping point for the material removal. It should be appreciated that the entire semiconductor device 100 may be flipped upside down to perform these operations.

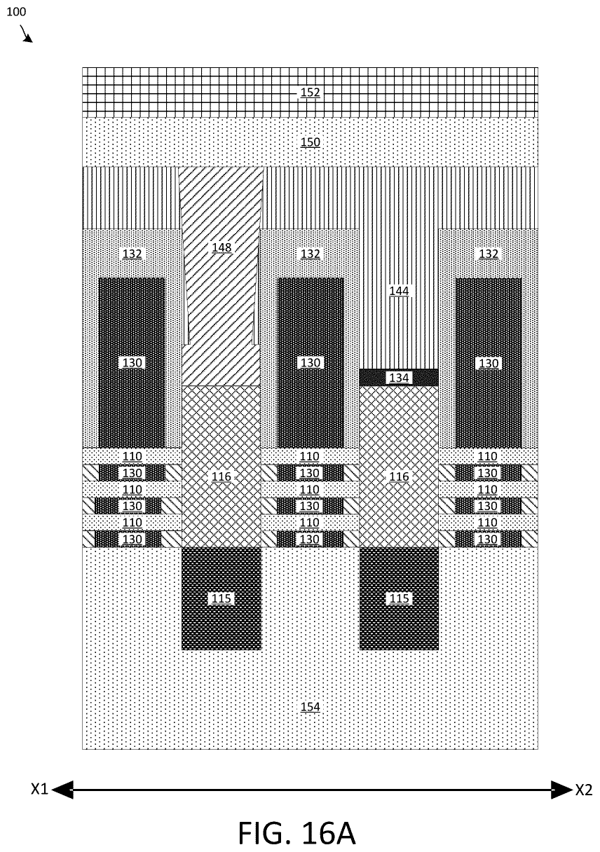

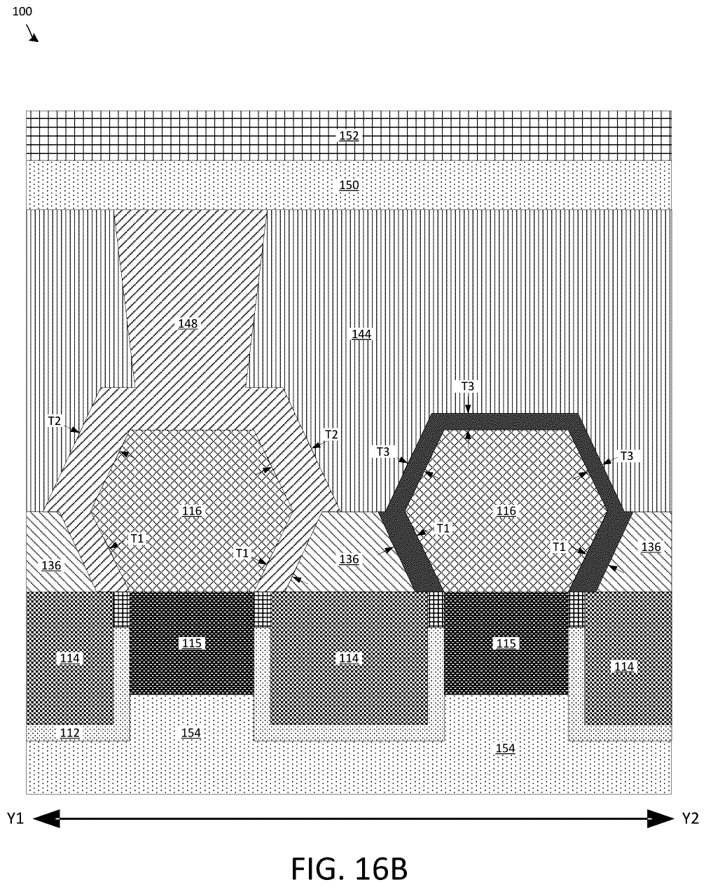

Referring now to FIGS. 16A and 16B, these figures are cross-sectional views of the semiconductor device of FIGS. 15A and 15B, respectively, at a subsequent stage of the fabrication process, according to embodiments. FIG. 16A is taken along the line X1-X2 from FIG. 1C, and FIG. 16B is taken along the line Y1-Y2 from FIG. 1C. As shown in FIGS. 16A and 16B, the etch stop layer 104 and all or most of the remaining material of the second substrate 106 is removed. This is followed by the formation of a fourth ILD layer 154 (this may also be referred to as a backside ILD layer).

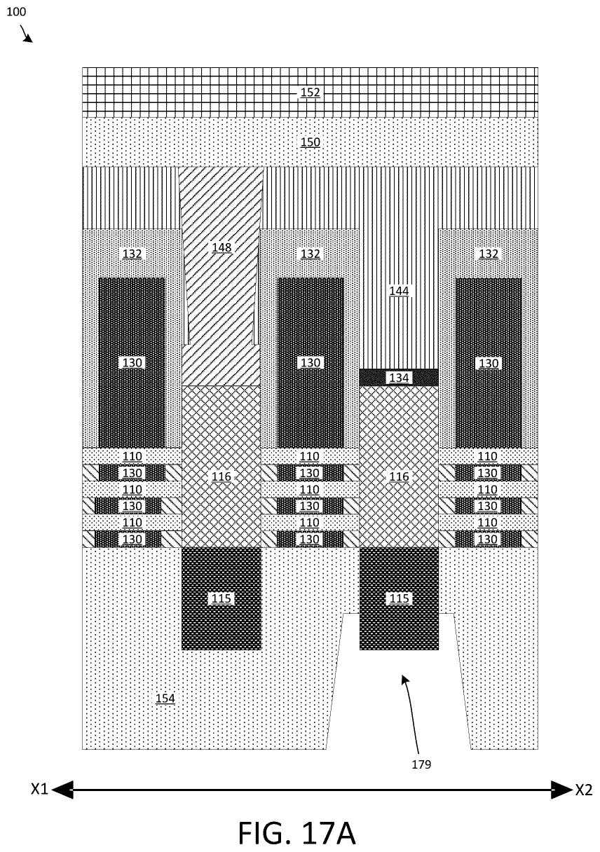

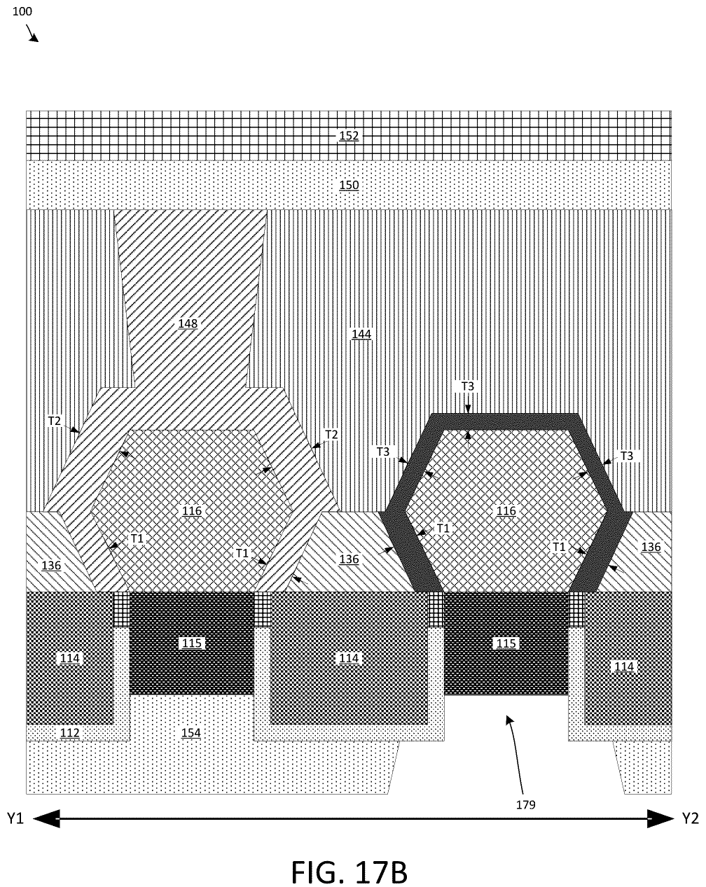

Referring now to FIGS. 17A and 17B, these figures are cross-sectional views of the semiconductor device of FIGS. 16A and 16B, respectively, at a subsequent stage of the fabrication process, according to embodiments. FIG. 17A is taken along the line X1-X2 from FIG. 1C, and FIG. 17B is taken along the line Y1-Y2 from FIG. 1C. As shown in FIG. 17A, a suitable material removal process is performed to form a backside contact opening 179 in the fourth ILD layer 154 to expose the right side source/drain placeholder layer 115 (on the X2 side of FIG. 17A). As shown in FIG. 17B, the material removal process also forms the backside contact opening 179 to expose the right side source/drain placeholder layer 115 (on the Y2 side of FIG. 17B). In certain examples, the material removal process may be a reactive ion etching (RIE) process or wet etching process, where the material of the fourth ILD layer 154 is selectively removed relative to the source/drain placeholder layer 115.

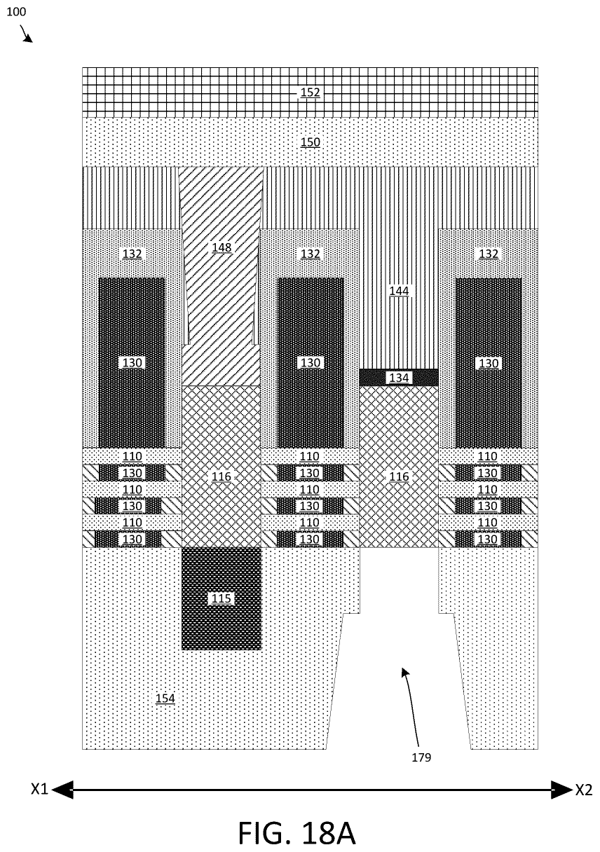

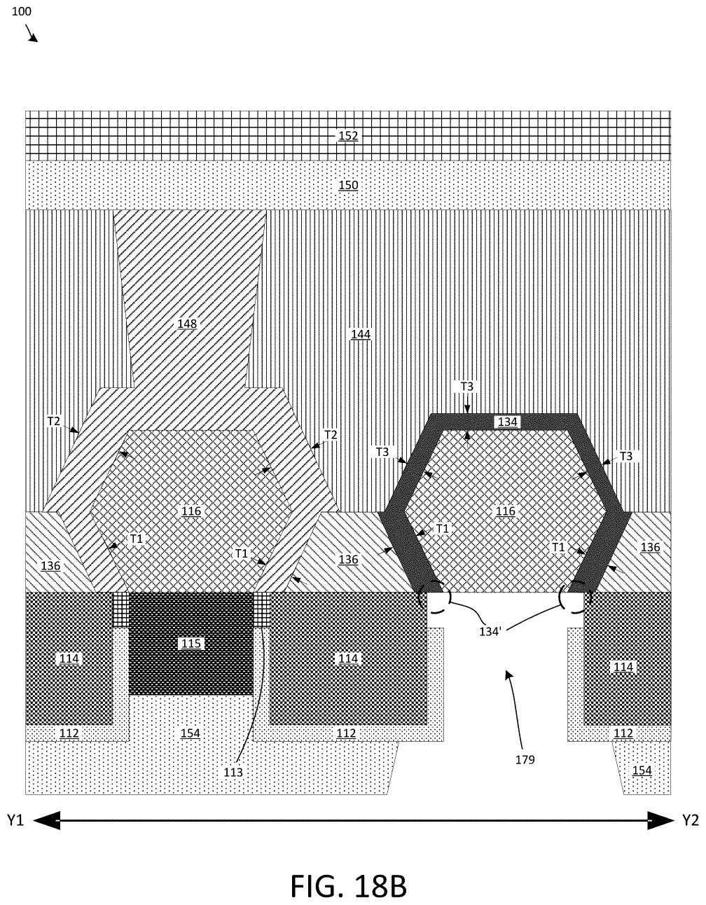

Referring now to FIGS. 18A and 18B, these figures are cross-sectional views of the semiconductor device of FIGS. 17A and 17B, respectively, at a subsequent stage of the fabrication process, according to embodiments. FIG. 18A is taken along the line X1-X2 from FIG. 1C, and FIG. 18B is taken along the line Y1-Y2 from FIG. 1C. As shown in FIG. 18A, a suitable material removal process is performed to remove the right side source/drain placeholder layer 115 (on the X2 side of FIG. 18A), thus further expanding the backside contact opening 179 to expose the right side S/D epitaxial layer 116. Thus, the material removal process (e.g., RIE or wet etching) selectively removes the material of the source/drain placeholder layer 115 without significantly removing material of the fourth ILD layer 154, the S/D epitaxial layer 116, the first STI liner layer 112 or the second STI liner layer 113. As shown in FIG. 18B, the material removal process also removes the right side source/drain placeholder layer 115 (on the Y2 side of FIG. 18B), thus further expanding the backside contact opening 179 to expose the right side S/D epitaxial layer 116.

Then, as shown in FIG. 18B, the second STI liner layer 113 (see also, FIG. 2B) is also removed with selective etching. This exposes at least a portion of the right side second epitaxial layer 134 (as indicated by areas 134′) to allow for subsequent removal of this sacrificial layer, as shown in FIG. 18B. It should be appreciated that the material of the second STI liner layer 113 is different than the material of the first STI liner layer 112 so that the second STI liner layer 113 can be selectively removed without significantly affecting the first STI liner layer 112. In particular, an appropriate etchant is chosen that allows the second STI liner layer 113 to be removed without significantly affecting the first STI liner layer 112, the second epitaxial layer 134 or the S/D epitaxial layer 116.

In certain embodiments, after the removal of the second STI liner layer 113, an optional lateral STI etching procedure (not shown) may be performed on the exposed portions of the STI regions 114 near areas 134′. In particular, an appropriate etchant may be chosen that will selectively remove the STI regions 114 near areas 134′ without significantly affecting the first STI liner layer 112, the second epitaxial layer 134, the source/drain epitaxial layer 116 or the fourth ILD layer 154. This may help to increase the amount of exposed surface area of the second epitaxial layer 134 near areas 134′, which may facilitate easier removal of the second epitaxial layer 134 in subsequent operations.

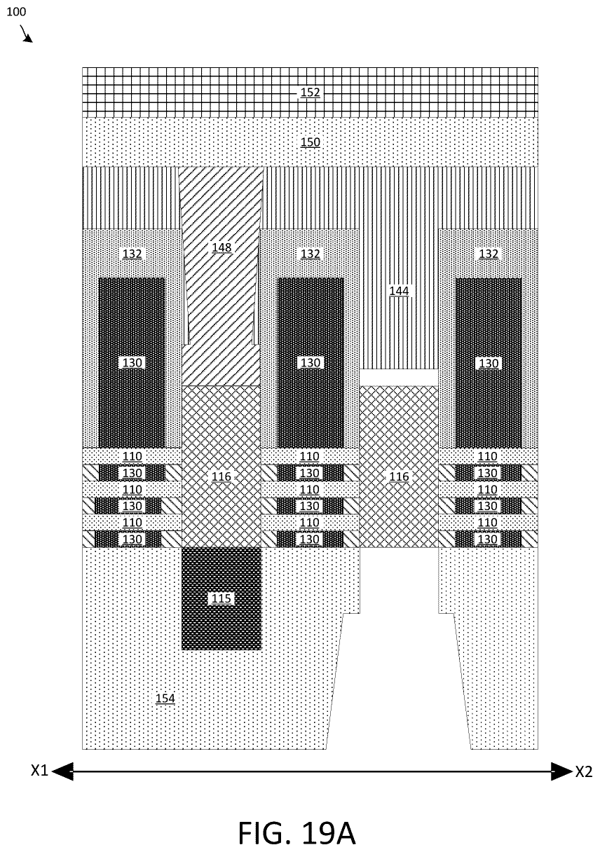

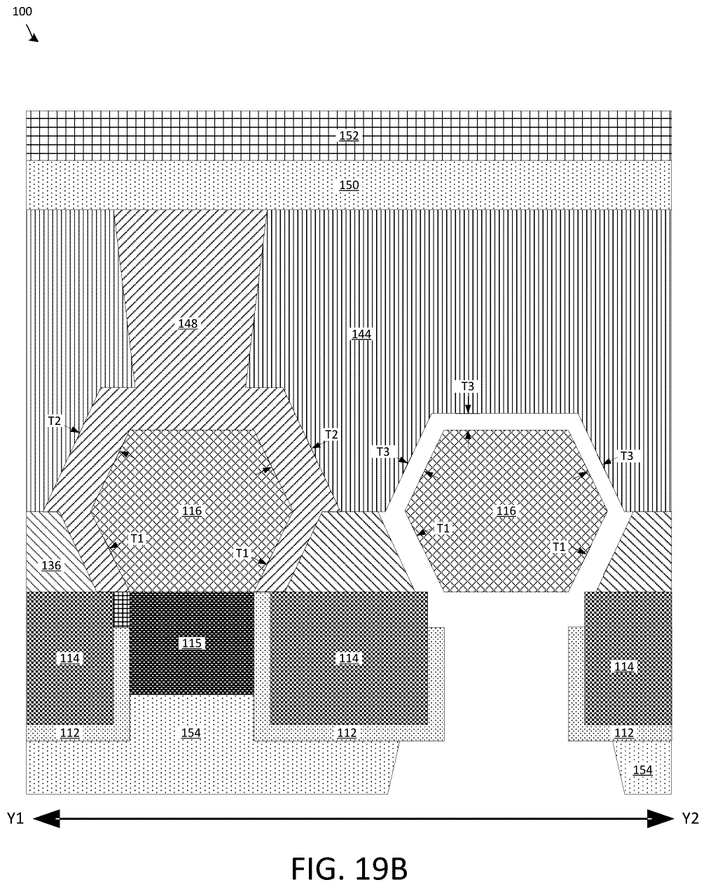

Referring now to FIGS. 19A and 19B, these figures are cross-sectional views of the semiconductor device of FIGS. 18A and 18B, respectively, at a subsequent stage of the fabrication process, according to embodiments. FIG. 19A is taken along the line X1-X2 from FIG. 1C, and FIG. 19B is taken along the line Y1-Y2 from FIG. 1C. As shown in FIG. 19A, a suitable material removal process is performed to remove the sacrificial material of the right side second epitaxial layer 134 (i.e., on the X2 side). As shown in FIG. 19B, the material removal process also removes the sacrificial material of the right side second epitaxial layer 134 (i.e., on the Y2 side). The material removal process may be, for example, a wet etching process. The removal of this sacrificial material of the right side second epitaxial layer 134 creates an opening, as seen in FIG. 19B, that extends around the right side S/D epitaxial layer 116 to allow for the subsequent formation of the wrap around metallization contacts. It should be appreciated that a suitable etchant may be chosen that selectively removes the second epitaxial layer 134 without significantly affecting the S/D epitaxial layer 116, the second ILD layer 136, the STI regions 114, the first STI liner layer 112 or the fourth ILD layer 154.

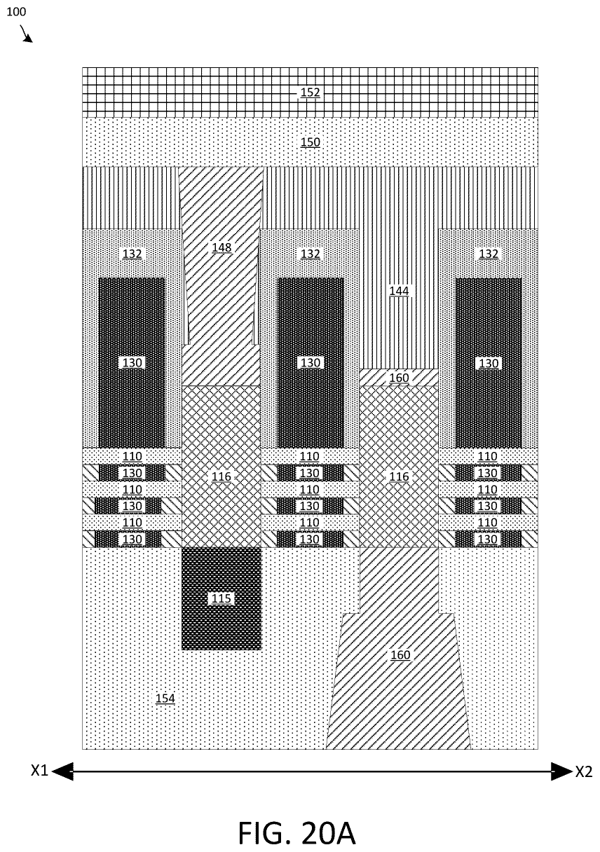

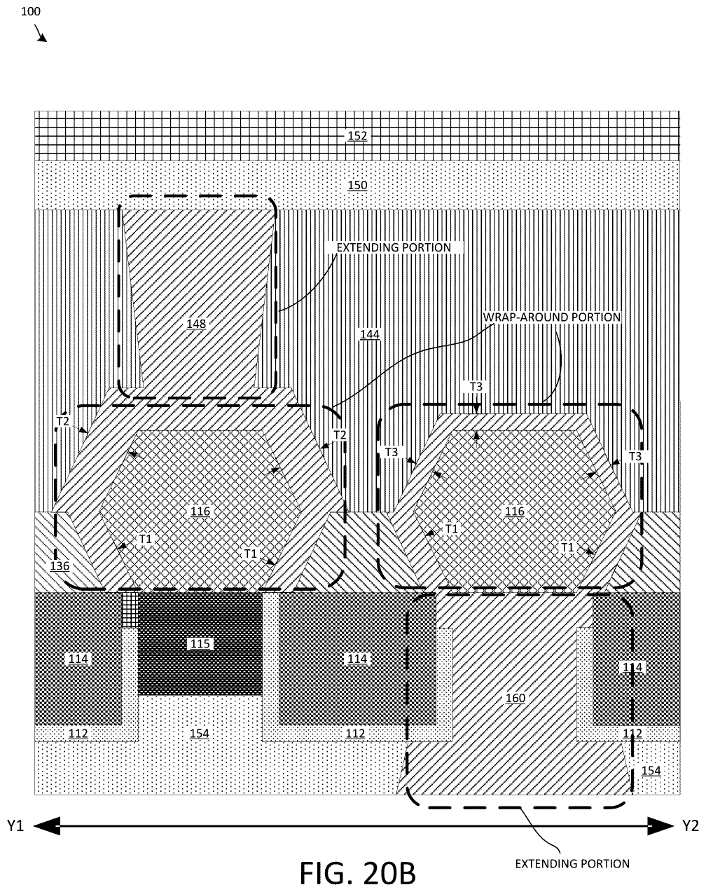

Referring now to FIGS. 20A and 20B, these figures are cross-sectional views of the semiconductor device of FIGS. 19A and 19B, respectively, at a subsequent stage of the fabrication process, according to embodiments. FIG. 20A is taken along the line X1-X2 from FIG. 1C, and FIG. 20B is taken along the line Y1-Y2 from FIG. 1C. As shown in FIG. 20A, a backside contact metallization 160 (or BSCA) is formed in the back side contact opening 179 to contact the right side S/D epitaxial layer 116 (on the X2 side). As shown in FIG. 20B, the backside contact metallization 160 is formed to wrap around the right side S/D epitaxial layer 116 (on the Y2 side). As shown in FIG. 20B, the resulting backside contact metallization 160 thus has a lower half portion with a thickness of T1 and an upper half portion with a thickness of T3, where T1>T3. It should also be noted that the thickness of the MOL contact metallization 148 for the upper portion of the left side S/D epitaxial layer 116 (as shown on the left side, or Y1 side, of FIG. 20B) has a thickness T2 that is greater than the thicknesses T3 and T1.

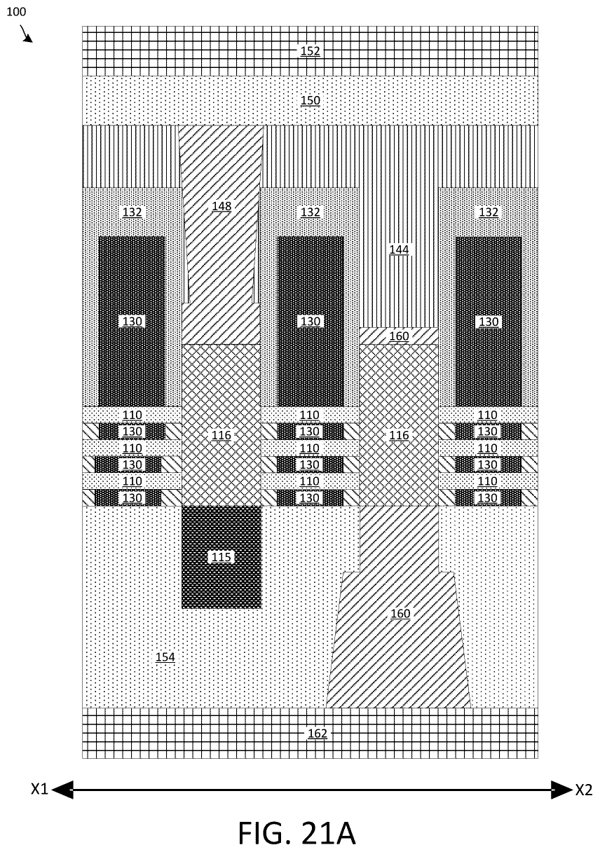

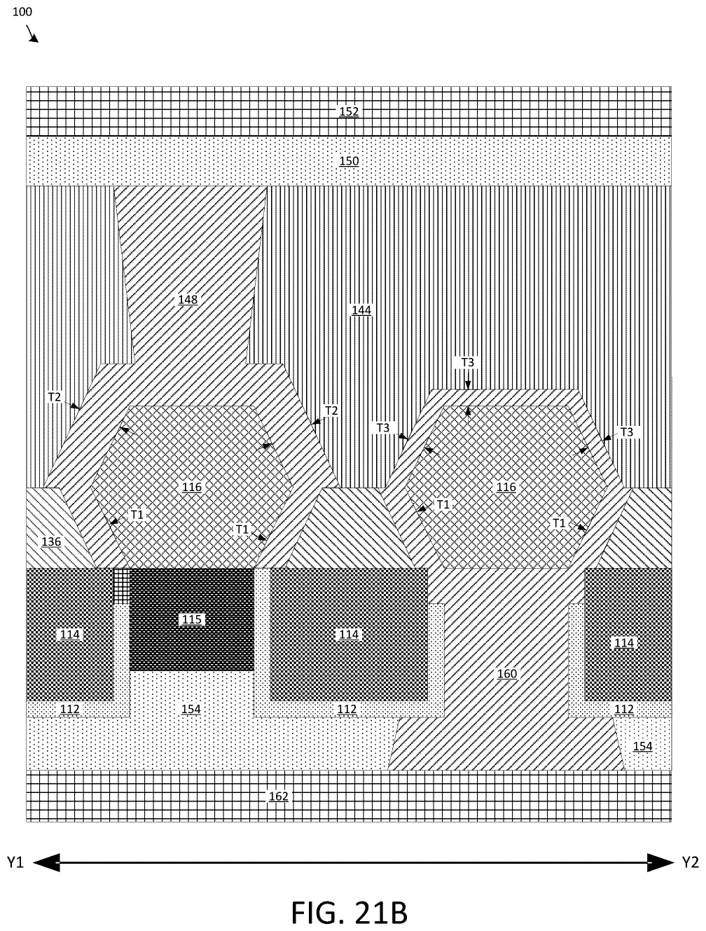

Referring now to FIGS. 21A and 21B, these figures are cross-sectional views of the semiconductor device of FIGS. 20A and 20B, respectively, at a subsequent stage of the fabrication process, according to embodiments. FIG. 21A is taken along the line X1-X2 from FIG. 1C, and FIG. 21B is taken along the line Y1-Y2 from FIG. 1C. As shown in FIGS. 21A and 21B, a backside power distribution network 162 is formed on the fourth ILD layer 154.

As shown and described above with respect to the embodiments of FIGS. 1A-21B, the thicknesses of various portions of the MOL contact metallization (CA) 148 and the backside contact metallization (BSCA) 160 vary depending on the side (e.g., the upper side or the lower side). As mentioned above, the MOL contact metallization 148 has an upper portion with a thickness T2 that is greater than a thickness T1 of the lower portion. With a lesser metal thickness T1, there is less contact to gate capacitance, but higher resistance. With the greater metal thickness T2, there is more contact to gate capacitance, but lower resistance. In these embodiments, the thicker metal portion that is closer to the contact opening (i.e., the side closer to the BEOL layer 150), and the thinner metal portion closer to the contact ends/tail (i.e., the side closer to the BSPDN layer 162), allows for the optimization of the capacitance and resistance of the device. In other words, having a relatively greater metal thickness toward the main contact side allows for more efficient delivery of current to the source/drain epitaxial layers (i.e., there is a lower probability of electron/current crowding with a thicker metal at the electron flow direction side, which is the side where the contacts connect to the BEOL layer 150 or BSPDN 162, respectively). Also, by having a relatively lesser metal thickness toward the side opposite where the contact connect to the BEOL or BSPDN, the lesser volume of metal can reduce the capacitance in that region between the contact (CA) and the gate (not shown). Thus, the present embodiments can achieve a capacitance decrease benefit without the penalty of a resistance increase.

Similarly, the BSDCA 160 has an upper portion with a thickness T3 that is less than a thickness T1 of the lower portion. With the greater metal thickness T1, there is more contact to gate capacitance, but lower resistance. With the lesser metal thickness T2, there is less contact to gate capacitance, but higher resistance.

Some embodiments of the present disclosure can take the form of a semiconductor device. The semiconductor device includes a nanosheet stack disposed on a substrate. The semiconductor device also includes a source/drain epitaxial layer disposed on the substrate adjacent to the nanosheet stack. The semiconductor device also includes a source/drain contact formed in contact with the source/drain epitaxial layer. The source/drain contact includes a wrap-around portion that wraps around sidewall surfaces of the source/drain epitaxial layer, and an extending portion that extends from the wrap-around portion, where the wrap-around portion has a non-uniform thickness. Having a source/drain contact with a non-uniform thickness may allow for having a greater metal thickness toward a main contact side that allows for more efficient delivery of current to the source/drain epitaxial layers. Also, by having a relatively lower metal thickness toward the side opposite to where the contact connects to the BEOL or BSPDN, the lesser volume of metal can reduce the capacitance in that region between the contact (also referred to as CA) and the gate electrode. Thus, the present embodiments may allow for an overall capacitance decrease benefit due to the thinner portion without incurring a resistance penalty due to the thicker portion.

In some embodiments of the semiconductor device, the wrap-around portion of the source/drain contact includes a first section and a second section. The second section of the wrap-around portion is nearer to the extending portion than the first section of the wrap-around portion. Also, the first section of the wrap-around portion has a first thickness, and the second section of the wrap-around portion has a second thickness that is greater than the first thickness. By having the thicker second section of the wrap-around portion nearer to the extending portion where current flows, this may allow for a decrease in the overall resistance of the device. This is beneficial because it allows for a lower drive current to be used. Also, by having the thinner section of the wrap-around portion on the opposite site relative to the thicker section, this may allow for a reduction in the capacitance in that region between the contact (CA) and the gate.

In some embodiments of the semiconductor device, the extending portion of the source/drain contact is connected to a back end of line (BEOL) layer. This may allow for an electrical connection to a BEOL side of the semiconductor device.

In some embodiments of the semiconductor device, the extending portion of the source/drain contact is connected to a backside power distribution network (BSPDN). This may allow for an electrical connection to the BSPDN side of the semiconductor device.

In some embodiments of the semiconductor device, the semiconductor device includes a source/drain placeholder layer in contact with a side of the source/drain epitaxial layer that is opposite to a side on which the extending portion of the source/drain contact is located. Although the source/drain placeholder does not affect the performance of the semiconductor device, this may allow for the formation of a second source/drain epitaxial region that electrically connects to a different side of the device. This may allow for increased flexibility where different source/drain epitaxial layers can be routed to different power delivery sources.

In some embodiments of the semiconductor device, the semiconductor device further includes a first STI liner layer in contact with sidewalls of the source/drain placeholder layer, and a second STI liner layer in contact with the first STI liner layer, the sidewalls of the source/drain placeholder layer, and the wrap-around portion of the source/drain contact. Although the first and second STI liner layers do not affect the performance of the semiconductor device, these may allow for the formation of a second source/drain epitaxial layer that electrically connects to a different side of the device. This may allow for increased flexibility where different source/drain epitaxial layers can be routed to different power delivery sources.

In some embodiments of the semiconductor device, the first STI liner layer has a different etching selectivity characteristic than the second STI liner layer. This may allow for selective removal of the second STI liner layer while retaining the first STI liner layer, and this may facilitate the formation of a second source/drain epitaxial layer by exposing a second epitaxial layer (or sacrificial epitaxial layer) that wraps around the second source/drain epitaxial layer. This may allow for increased flexibility where different source/drain epitaxial layers can be routed to different power delivery sources.

In some embodiments of the semiconductor device, the semiconductor device further includes a second source/drain epitaxial layer disposed on the substrate adjacent to the nanosheet stack. The second source/drain contact is formed in contact with the second source/drain epitaxial layer, and the second source/drain contact includes a second wrap-around portion that covers sidewall surfaces of the second source/drain epitaxial layer. The second source/drain contact also includes a second extending portion that extends from the second wrap-around portion in a second extending direction that is opposite to a first extending direction of the extending portion. In these embodiments, the second wrap-around portion also has a non-uniform thickness. This may allow for achieving the capacitance and resistance reductions similar to the source/drain contact discussed above, while also enabling increased flexibility where different source/drain epitaxial layers can be routed to different power delivery sources, such as a BEOL layer or a BSPDN.

In some embodiments of the semiconductor device, the second wrap-around portion of the second source/drain contact includes a first section and a second section. The second section of the second wrap-around portion is nearer to the second extending portion than the first section of the second wrap-around portion. Also, the first section of the second wrap-around portion has a third thickness, and the second section of the second wrap-around portion has the first thickness, where the second thickness is greater than the first thickness which is greater than the third thickness. Thus, for each of the source/drain contact and the second source/drain contact, the different thicknesses of the respective first and second sections of the wrap-around portions can be tailored to effect a reduction in the overall capacitance and resistance of the semiconductor device even when the electrical connections for the source/drain epitaxial layer and the second source/drain epitaxial layer are routed to different sides of the semiconductor device.

In some embodiments of the semiconductor device, the extending portion of the source/drain contact is connected to a BEOL layer, and the second extending portion of the second source/drain contact is connected to a BSPDN. This may allow for a reduction in the overall capacitance and resistance of the semiconductor device even when the electrical connections for the source/drain epitaxial layer and the second source/drain epitaxial layer are routed to different sides of the semiconductor device.

In some embodiments of the semiconductor device, the second wrap-around portion of the second source/drain contact also covers a surface of the second source/drain epitaxial layer that is opposite to a side that the second extending portion is located. The additional material of the second wrap-around portion of the second source/drain contact may allow for a further reduction in capacitance of the semiconductor device due to the reduced thickness of this portion.

In some embodiments of the semiconductor device, the nanosheet stack includes a gate electrode.

In some embodiments of the semiconductor device, a SiOC based gate cap is formed on the gate electrode, and a SiOC based gate spacer is formed on sidewalls of the gate electrode and the gate cap. This may allow for electrical isolation between the gate electrode and the source/drain contacts.

In some embodiments of the semiconductor device, a transition between the first section of the wrap-around portion and the second section of the wrap-around portion is at a middle level of the source/drain epitaxial layer. This may allow for roughly half of the source/drain contact to have a greater thickness which enables the resistance decrease benefit, and this may also allow for roughly half of the source/drain contact to have a lesser thickness which enables the capacitance decrease benefit.

Some embodiments of the present disclosure can take the form of an electronic device. The electronic device includes a semiconductor device including a nanosheet stack disposed on a substrate. The semiconductor device also includes a source/drain epitaxial layer disposed on the substrate adjacent to the nanosheet stack. The semiconductor device also includes a source/drain contact formed in contact with the source/drain epitaxial layer. The source/drain contact includes a wrap-around portion that wraps around sidewall surfaces of the source/drain epitaxial layer, and an extending portion that extends from the wrap-around portion, where the wrap-around portion has a non-uniform thickness. Having a source/drain contact with a non-uniform thickness may allow for having a greater metal thickness toward a main contact side that allows for more efficient delivery of current to the source/drain epitaxial layers. Also, by having a relatively lower metal thickness toward the side opposite to where the contact connects to the BEOL or BSPDN, the lesser volume of metal can reduce the capacitance in that region between the contact (also referred to as CA) and the gate electrode. Thus, the present embodiments may allow for an overall capacitance decrease benefit due to the thinner portion without incurring a resistance penalty due to the thicker portion.

In some embodiments of the electronic device, the wrap-around portion of the source/drain contact includes a first section and a second section. The second section of the wrap-around portion is nearer to the extending portion than the first section of the wrap-around portion. Also, the first section of the wrap-around portion has a first thickness, and the second section of the wrap-around portion has a second thickness that is greater than the first thickness. By having the thicker second section of the wrap-around portion nearer to the extending portion where current flows, this may allow for a decrease in the overall resistance of the device. This is beneficial because it allows for a lower drive current to be used. Also, by having the thinner section of the wrap-around portion on the opposite site relative to the thicker section, this may allow for a reduction in the capacitance in that region between the contact (CA) and the gate.

In some embodiments of the electronic device, the extending portion of the source/drain contact is connected to a back end of line (BEOL) layer. This may allow for an electrical connection to a BEOL side of the semiconductor device.

In some embodiments of the electronic device, the extending portion of the source/drain contact is connected to a backside power distribution network (BSPDN). This may allow for an electrical connection to the BSPDN side of the semiconductor device.

In some embodiments of the electronic device, the semiconductor device further includes a second source/drain epitaxial layer disposed on the substrate adjacent to the nanosheet stack. The second source/drain contact is formed in contact with the second source/drain epitaxial layer, and the second source/drain contact includes a second wrap-around portion that covers sidewall surfaces of the second source/drain epitaxial layer. The second source/drain contact also includes a second extending portion that extends from the second wrap-around portion in a second extending direction that is opposite to a first extending direction of the extending portion. In these embodiments, the second wrap-around portion also has a non-uniform thickness. This may allow for achieving the capacitance and resistance reductions similar to the source/drain contact discussed above, while also enabling increased flexibility where different source/drain epitaxial layers can be routed to different power delivery sources, such as a BEOL layer or a BSPDN.

In some embodiments of the electronic device, the second wrap-around portion of the second source/drain contact includes a first section and a second section. The second section of the second wrap-around portion is nearer to the second extending portion than the first section of the second wrap-around portion. Also, the first section of the second wrap-around portion has a third thickness, and the second section of the second wrap-around portion has the first thickness, where the second thickness is greater than the first thickness which is greater than the third thickness. Thus, for each of the source/drain contact and the second source/drain contact, the different thicknesses of the respective first and second sections of the wrap-around portions can be tailored to effect a reduction in the overall capacitance and resistance of the semiconductor device even when the electrical connections for the source/drain epitaxial layer and the second source/drain epitaxial layer are routed to different sides of the semiconductor device.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a nanosheet stack disposed on a substrate;
a source/drain epitaxial layer disposed on the substrate adjacent to the nanosheet stack; and
a source/drain contact formed in contact with the source/drain epitaxial layer, the source/drain contact including
a wrap-around portion that wraps around sidewall surfaces of the source/drain epitaxial layer, and
an extending portion that extends from the wrap-around portion,
wherein the wrap-around portion has a non-uniform thickness.

2. The semiconductor device of claim 1,
wherein the wrap-around portion of the source/drain contact includes a first section and a second section, the second section of the wrap-around portion being nearer to the extending portion than the first section of the wrap-around portion, and
wherein the first section of the wrap-around portion has a first thickness, and the second section of the wrap-around portion has a second thickness that is greater than the first thickness.

3. The semiconductor device of claim 1, wherein the extending portion of the source/drain contact is connected to a back end of line (BEOL) layer.

4. The semiconductor device of claim 1, wherein the extending portion of the source/drain contact is connected to a backside power distribution network (BSPDN).

5. The semiconductor device of claim 2, further comprising a source/drain placeholder layer in contact with a side of the source/drain epitaxial layer that is opposite to a side on which the extending portion of the source/drain contact is located.

6. The semiconductor device of claim 5, further comprising:
a first STI liner layer in contact with sidewalls of the source/drain placeholder layer; and
a second STI liner layer in contact with the first STI liner layer, the sidewalls of the source/drain placeholder layer, and the wrap-around portion of the source/drain contact.

7. The semiconductor device of claim 6, wherein the first STI liner layer has a different etching selectivity characteristic than the second STI liner layer.

8. The semiconductor device of claim 2, further comprising:
a second source/drain epitaxial layer disposed on the substrate adjacent to the nanosheet stack;
a second source/drain contact formed in contact with the second source/drain epitaxial layer, the second source/drain contact including
a second wrap-around portion that covers sidewall surfaces of the second source/drain epitaxial layer, and
a second extending portion that extends from the second wrap-around portion in a second extending direction that is opposite to a first extending direction of the extending portion,
wherein the second wrap-around portion has a non-uniform thickness.

9. The semiconductor device of claim 8,
wherein the second wrap-around portion of the second source/drain contact includes a first section and a second section, the second section of the second wrap-around portion being nearer to the second extending portion than the first section of the second wrap-around portion, and
wherein the first section of the second wrap-around portion has the third thickness, and the second section of the second wrap-around portion has the first thickness, where the second thickness is greater than the first thickness which is greater than the third thickness.

10. The semiconductor device of claim 8,
wherein the extending portion of the source/drain contact is connected to a BEOL layer, and
wherein the second extending portion of the second source/drain contact is connected to a BSPDN.

11. The semiconductor device of claim 8, wherein the second wrap-around portion of the second source/drain contact also covers a surface of the second source/drain epitaxial layer that is opposite to a side that the second extending portion is located.

12. The semiconductor device of claim 1, wherein the nanosheet stack includes a gate electrode.

13. The semiconductor device of claim 12, further comprising:
a SiOC based gate cap formed on the gate electrode; and
a SiOC based gate spacer formed on sidewalls of the gate electrode and the gate cap.

14. The semiconductor device of claim 2, wherein a transition between the first section of the wrap-around portion and the second section of the wrap-around portion is at a middle level of the source/drain epitaxial layer.

15. An electronic device comprising:
a semiconductor device including
a nanosheet stack disposed on a substrate;
a source/drain epitaxial layer disposed on the substrate adjacent to the nanosheet stack; and
a source/drain contact formed in contact with the source/drain epitaxial layer, the source/drain contact including
a wrap-around portion that wraps around sidewall surfaces of the source/drain epitaxial layer, and
an extending portion that extends from the wrap-around portion,
wherein the wrap-around portion has a non-uniform thickness.

16. The electronic device of claim 15,
wherein the wrap-around portion of the source/drain contact includes a first section and a second section, the second section of the wrap-around portion being nearer to the extending portion than the first section of the wrap-around portion, and
wherein the first section of the wrap-around portion has a first thickness, and the second section of the wrap-around portion has a second thickness that is greater than the first thickness.

17. The electronic device of claim 15, wherein the extending portion of the source/drain contact is connected to a back end of line (BEOL) layer.

18. The electronic device of claim 15, wherein the extending portion of the source/drain contact is connected to a backside power distribution network (BSPDN).

19. The electronic device of claim 16, further comprising:
a second source/drain epitaxial layer disposed on the substrate adjacent to the nanosheet stack;
a second source/drain contact formed in contact with the second source/drain epitaxial layer, the second source/drain contact including
a second wrap-around portion that covers sidewall surfaces of the second source/drain epitaxial layer, and
a second extending portion that extends from the second wrap-around portion in a second extending direction that is opposite to a first extending direction of the extending portion,
wherein the second wrap-around portion has a non-uniform thickness.

20. The electronic device of claim 19,
wherein the second wrap-around portion of the second source/drain contact includes a first section and a second section, the second section of the second wrap-around portion being nearer to the second extending portion than the first section of the second wrap-around portion, and
wherein the first section of the second wrap-around portion has the third thickness, and the second section of the second wrap-around portion has the first thickness, where the second thickness is greater than the first thickness which is greater than the third thickness.
